(19) United States
(12) Patent Application Publication
(10) Pub. No.: US 2011/0232761 A1
(43) Pub. Date: Sep. 29, 2011

(54) SOLAR PHOTOVOLTAIC DEVICES HAVING OPTIONAL BATTERIES

(76) Inventor: Henry L. LOMASNEY, Pagosa Springs, CO (US)

(21) Appl. No.: 13/051,976

(22) Filed: Mar. 18, 2011

Related U.S. Application Data
(60) Provisional application No. 61/315,330, filed on Mar. 18, 2010.

(51) Int. Cl. H01L 31/0272; H01M 10/46

(52) U.S. Cl. 136/262; 438/95; 320/101; 257/E31.008

(57) ABSTRACT

Solar photovoltaic (PV) devices, e.g., those based on the Copper Indium Selenide (CIS) family of absorbers, including CuIn₍₁₋ₓ₎Ga₍ₓ₎Se₂ (CIGS) absorber thin-film PV devices, are provided. Embodiments provide PV devices comprising an alkali metal-containing polymeric film (ACPF), which is a film formed from a composite comprising an alkali metal-containing material and a polymer. Embodiments of this disclosure also provide PV devices comprising a thermally stable polymer film that does not contain an alkali metal (TSP). Included within the embodiments of this disclosure are flexible PV devices comprising a flexible base substrate onto which one or more ACPFs and/or TSPs is/are provided, as well as flexible PV devices wherein an ACPF or TSP itself constitutes the base substrate in the form of a stand alone film. Processes for making such flexible PV devices include roll-to-roll processes. PV devices disclosed herein will provide improved energy conversion efficiencies as a result of the delivery of sodium dopant into the absorber layer. Also disclosed are combinations of such PV devices and batteries that may store energy generated from the PV absorber. This disclosure also relates to shunt circuits for connecting the PV absorber to a battery in a combination PV/battery device and to array connectors for connecting such PV devices, either with or without batteries.

This application claims the benefit of priority to U.S. Provisional Patent Application No. 61/315,330, filed Mar. 18, 2010, the disclosure of which is incorporated by reference in its entirety.

### FIELD OF THE DISCLOSURE

This disclosure includes photovoltaic (PV) devices and polymeric films for making them. The PV devices may include Copper Indium Selenide (CIS) absorbers, including a CuIn₍₁₋ₓ₎Ga₍ₓ₎Se₂ (CIGS) absorber. This disclosure also relates to combinations of such PV devices and batteries that may store energy generated from the PV absorber. This disclosure also relates to connectors for connecting such PV devices, either with or without batteries.

### SUMMARY OF THE DISCLOSURE

Embodiments of this disclosure provide PV devices comprising an alkali metal-containing polymeric film (ACPF), which is a film formed from a composite comprising an alkali metal-containing material and a polymer. Included within such embodiments are flexible PV devices comprising a flexible base substrate onto which an ACPF is provided, as well as flexible PV devices wherein the ACPF constitutes the base substrate in the form of a stand alone film. Embodiments of PV devices disclosed herein will provide improved energy conversion efficiencies as a result of the delivery of sodium dopant into the absorber layer.

Embodiments of this disclosure also provide PV devices comprising a thermally stable polymer film that does not contain an alkali metal (TSP). Such TSPs advantageously will be able to withstand high processing temperatures of the magnitude that are typically encountered in the production of the device, e.g., 500° C. and higher, for at least five minutes. Included within such embodiments are flexible PV devices comprising a flexible base substrate onto which this TSP is provided, as well as flexible PV devices wherein the TSP itself constitutes the base substrate in the form of a stand alone film. All of the embodiments described in this disclosure for products comprising an ACPF and processes for making the products comprising an ACPF thus apply equally to products in which the ACPF is replaced by a TSP that does not contain alkali metal. Of course, the TSP will not provide a source of alkali metal and thus such embodiments will be useful, e.g., where it is not necessary or desirable to provide alkali metal to the absorber from such a polymer layer.

Embodiments of this disclosure also provide methods for manufacturing such PV devices. Included within such methods are embodiments of single sheet and roll-to-roll processing methods for manufacturing flexible PV devices comprising an optional flexible base substrate material, an ACPF or TSP layer, and a light absorbing layer (CIS and CIGS). Such PV devices also may comprise one or more additional layers, e.g., a transparent electrical conductive layer. The PV devices also may comprise, where appropriate, a backside electrode layer such as one that comprises molybdenum or other appropriate conductor.

Embodiments of this disclosure also provide PV devices that comprise an ACPF that is designed to enhance a flexible substrate's ability to withstand high processing temperatures of the magnitude that are typically encountered in the production of the device, e.g., 500° C. and higher, and which under such temperatures will provide a source of alkali ions to the CIS or CIGS absorber. Such alkali ions can enhance the photoelectric conversion efficiency of the PV device. Embodiments of the PV devices disclosed herein thus can provide good to excellent energy conversion efficiencies, including efficiencies above 10%, above 15% and above 17%. Advantageously, such ACPFs also can provide dimensional stability to the PV device, e.g., when the substrate material is a polymer film.

Other embodiments provide flexible PV devices comprising a flexible substrate such as a metal or polymer. Such devices comprise an ACPF or TSP above the substrate, an electrode above the ACPF or TSP, an absorber above the electrode, and another electrode above the absorber. A second polymer is then provided below the substrate, which polymer advantageously provides thermal and/or dimensional stability to the substrate and PV device. This second polymer layer may provide good thermal resistance, including for temperatures up to 500° C. or higher. Such embodiments can include a flexible polymer substrate which also has good thermal resistance.

Other embodiments described herein provide combination PV/battery devices in which batteries are provide in combination with a PV device. The battery may be fabricated as part of the PV device or may be fabricated separately and then attached or otherwise places connected to the to the PV device so as to permit current from the PV device to flow into the battery.

Yet other embodiments provide connectors for connecting multiple PV devices, which devices may or may not include a battery as disclosed herein.

### BRIEF DESCRIPTION OF THE FIGURES

FIGS. 1-3 are secondary ion mass spectrometry (“SIMS”) results of CIGS absorber layers that were deposited on substrates comprising ACPF layers prepared in accordance with embodiments of this disclosure.

FIG. 4 is a SIMS analysis of an absorber layer that was deposited on a substrate comprising crystalline glass.

FIG. 5 is a diagram of one embodiment of an electrical circuit that may be used with combination PV/battery device.

FIG. 6 is a schematic of an embodiment of a combination PV/battery device in which the PV absorber and battery share a common supporting substrate.

FIG. 7 illustrates an embodiment of a connector for connecting multiple PV/battery devices as described herein.

FIG. 8 shows a diode interconnect designed in such a manner that the P-type semiconductor material is connected to the positive terminal of the battery and the N-type semiconductor material is connected to the negative terminal.

FIG. 9 illustrates a reverse biased diode.

### EMBODIMENTS OF THE ACPFs AND TSPs

The Film-Forming Polymer

The ACPF and/or TSP layer, when properly applied to a flexible substrate, should be able withstand the subsequent CIS or CIGS absorber layer deposition activity without substantial degradation or excessive off-gassing. Deposition of the absorber layer typically involves processing at high temperatures, often in the range of at least 500° C.

As mentioned above, the ACPF is a film formed from a composite comprising an alkali metal-containing material and a film-forming polymer. Examples of acceptable film-forming polymers that can be used in the design of the ACPF include polyimide-imide (PII), poly(pyromellitic dianhydride-CO-4,4′-oxydianiline) amic acid, polyamide-imide (PAI), polyphenyl sulfone (PPSU), polyethersulfone (PES), polsulfone (PSU), polyetheretherketone (PEEK) high temperature sulfone resins, self-reinforced polyphenylene, polybenzimidizole (PBI), polyimide (PI), polyetherimide (PEI), polyphenylene sulfide (PPS), polyhedryal oligomeric silsesquioxanes and high temperature tolerant silicone or polysiloxane hardcoat resin. Each of these polymers may be used alone or as an additive to another polymer such as those in this group of film forming polymers. TSPs may be prepared from the same film-forming polymers.

The polymer that is used in the ACPF and/or TSP necessarily should be soluble in a solvent such that a composite coating type medium can be produced. Suitable solvents typically will include organic solvents, which are well known to skilled artisans. Such organic solvents include, for example, dipolar aprotic solvents such as N-methyl pyrrolidone (NMP), dimethylacetamide (DMAC), dimethylsulfoxide (DMSO) and dimethylformamide (DMF).

One example of a polyamide-imide polymer that can be used in the ACPF or TSP is produced by Solvay Advanced Polymers Inc whose tradename is Torlon 4000 T. Examples of suitable solvent for Torlon 4000 T are dipolar aprotic solvents such as N-methyl pyrrolidone (NMP), dimethylacetamide (DMAC), dimethylsulfoxide (DMSO) and dimethylformamide (DMF). A specific example is 1-methyl-2-pyrrolidinone.

The Torlon 4000T can be used alone or in blends with other polymers such as polyphenylsulfone (PPSU), polyethersulfone (PES), polysulfone (PSU), polyetheretherketone (PEEK), high-temperature sulfone resins, self-reinforced polyphenylene, polybenzimidizole (PBI), polyimide (PI), polyetherimide (PEI), and polyphenylene sulfide (PPS). In addition to blending with other polymers to enhance properties, Torlon 4000T may be compounded with a wide variety of performance fillers, reinforcements, specialty additives and colorants to meet the desired application.

Upon curing the Torlon 4000 T, the polyamide-imide structure of this polymer is converted to a polyimide structure. This conversion takes place when the polymer is subjected to a temperature regime of approximately 200° C. While not wishing to be bound by any particular theory, it is believed that this transition to the polyimide structure involves the conversion of polyamide sites to polyimide sites via a process that takes place at the nitrogen sites and involves the liberation of a water molecule.

Another example of a suitable polymer blend was achieved by blending a polyimide polymer with a polyhedral oligomeric silsesquioxane (POSS). The polyimide polymer is provided in the form of the polyamic acid pre-polymer before heat treatment. After the heat treatment step, which is introduced to the system during the curing of the applied wet film solution, the polyimide polymer structure is achieved. Such a polyimide polymer precursor solution was obtained from RBI Incorporated as product number PI 1388. The POSS additive was obtained from Hybrid Plastics as product number SO-1450 which is described as having a phenyl tri silanol structure. This resulting polymer blend composition was seen to deliver high thermal decomposition temperatures which exceeded 500 degrees C. Furthermore, this blend exhibited small dimensional changes when heating to 400 degrees C.

The Alkali Metal-Containing Material

The alkali metal in the ACPF can comprise any one or a combination of the alkali metals of group IA of the periodic table, but typically the alkali metal will be one or a combination of sodium (Na), potassium (K) and/or lithium (Li). The alkali metal may be in any form that will provide alkali ions to the CIS or CIGS absorber. Such alkali metal-containing materials also may be used in an anhydrous form, which can be advantageous in some embodiments. The alkali metals may be provided through migration from the ACPF into the CIS and CIGS absorber media to serve there as dopants for enhanced hole carrier concentration and improved open circuit voltage.

Sodium-containing materials can provide an advantageous choice for an alkali metal-containing material because they are readily available in many different compounds and forms and can provide acceptable results in the embodiments of this disclosure. For example, the following compounds are examples of sodium-containing materials that may be used in embodiments of this disclosure: Na, Na₂O, NaOH, NaF, NaCl, NaI, Na₂S, Na₂Se, NaNO₃, NaSiO₂, NaCO₃. Such materials are available in various forms, e.g., soda lime glass flakes, powders, particles, fibers, ribbons, woven glass fiber fabrics or “veils”, and microspheres. Where a sodium-containing material is desired, the desired performance characteristics of the ACPF will affect the selection of the sodium-containing compound (or compounds) and form of the material. These characteristics will include the ability of the sodium-containing compound to liberate the sodium at the desired temperature and in the desired amount during the absorber deposition process. Additional considerations are the compatibility of the sodium-containing material with the polymer medium, the ease with which the sodium-containing material can be incorporated into the ACPF and the cost. Skilled artisans will be able through routine experimentation to find one or more acceptable sodium-containing compounds for the specific process used and PV device being made.

Specific examples of a sodium-containing material that may be incorporated into the ACPF include materials supplied by PQ Corporation. The SS-C-200 provided by PQ Corp. may be especially useful in embodiments because it is supplied as an anhydrous material. Particle size of this filler material is such that 97% will pass through a 200 mesh screen. The weight percent of Na₂O is 37.7 percent and the SiO₂ is 65.4 percent. Examples of other sodium-containing materials that may be used include sodium selenide (Na₂Se) and sodium fluoride (NaF). Another example is Advera 401 PS which is an aluminosilicate filler. This is a zeolite sodium A powder. Mean particle size of this powder is approximately 5 microns.

Adjusting the loading level of the alkali metal in the ACPF formula provides one way to adjust/optimize the amount of alkali metal that is made available during the CIGS deposition process. Accordingly, once the desired availability of alkali metal for the CIGS deposition process is determined, routine experimentation can establish the appropriate alkali metal form and loading level needed to achieve such availability. The alkali metal concentration, as a percent of the total weight of the cured ACPF, can range from, for example, 0.01 to 10 percent, although higher amounts certainly may be possible and desirable depending on the design and fabrication of the PV device. Within the above range, amounts of from 0.1 to 6 percent, or from 0.1 to 4 percent may provide acceptable results, again depending on the design and fabrication of the PV device, including the processing parameters such as the temperature(s) that is/are involved in its production.

Glass flakes that may be used can include a soda lime material. Such glass flakes are available in a wide range of geometries, flake sizes, surface areas and aspect ratios. An acceptable geometry of the glass flake is one that delivers a desired percentage by weight of filler as a percent of the total weight of the ACPF film. Of course, acceptable ranges of loading for different forms, e.g., flakes, fibers, microspheres and fine powders may be different, as may the loading for different types of each form. Other acceptable alkali metal containing glass fillers include glass fibers, glass microspheres, and fine glass powders.

Other considerations in the selection of the filler form (or combinations of forms) and a corresponding loading level are (i) the contribution of the filler to the enhanced thermal tolerance of the ACPF, and (ii) the contribution of the filler to the matching of the coefficient of thermal expansion (CTE) of the substrate to that of the CIGS absorber layer (discussed below). The resulting composite is advantageously one that is relatively easy to apply, highly reliable and predictable in terms of its contribution of Na metal to the CIGS absorber layer, and sufficiently thermally tolerant and dimensionally stable so as to contribute to (i) reliable fabrication of the device (including deposition of the absorber layer) and (ii) long term physical integrity and operational reliability of the PV device. In advantageous embodiments, the resulting composite also provides alkali metal to the absorber during deposition so as to yield an absorber with a substantially uniform distribution of alkali metal (e.g., sodium) throughout much of the thickness of the absorber. In embodiments where the ACPF is employed as the primary substrate for the PV device, the ACPF's physical integrity may become a more important consideration, as compared to a design wherein the ACPF is applied to a flexible base film substrate, such as a polymer film or metal foil. Of course, a cost effective composite also is desirable.

As stated above, the resulting composite is advantageously one that is relatively easy to apply and, when cured, provides a film that has sufficient thermal tolerance and dimensional stability to permit fabrication of the PV device including deposition of the absorber layer. One example of a glass flake material that can provide acceptable results is Microglas RCF-160, produced by Nippon Sheet Glass, which is 9-13 percent Na₂O and of nominal particle size that is 160 microns with 65 percent of the weight content having a thickness range of 40-160 microns.

As mentioned above, another form of alkali metal-containing material that may be employed is soda lime glass microspheres. One such filler that may provide acceptable results is produced by 3M Corporation under the tradename of Zeospheres, which is a soda lime glass sphere designated as 3M S-60/10,000.

Multiple forms of such material may be used in making the ACPF. For example, combinations of forms may give more uniform loading because the spatial packing of different forms can yield better usage of the volume provided in the relatively thin polymer layer. Such increased spatial packing also may be advantageous when, e.g., the optional surface modification (discussed below) is to be employed because it may provide a higher overall percentage of alkali-metal containing material at the surface following finishing and thus a potentially a smoother surface with fewer defects such as pits, craters or other imperfections. Multiple forms also may yield a more desirable profile of alkali metal release to the absorber. For example, some forms may release alkali metal more quickly and/or at a lower temperature, while others may provide a delayed or slower release, and/or a release at higher temperatures, such that selection of combinations with different release characteristics could provide an overall more uniform and/or either a short or sustained release across a greater timeframe or range of processing temperatures. The introduction of glass in the form of a relatively short glass fiber medium as well as in the form of a woven veil can be used to enhance the structural properties of the ACPF. Such glass forms also may provide advantageous structural properties to the cured ACPF, including in those embodiments where the ACPF is the primary supporting substrate for the PV device.

As stated above, the supply of alkali metal to the environment surrounding the CIGS during the deposition and annealing process may be affected by the form(s), loading and concentration of the alkali metal-containing material in the ACPF. The supply further may be influenced and/or controlled by altering the thickness of the ACPF and/or providing multiple layers of ACPFs. Different thicknesses of ACPFs and ACPFs made from different polymers can provide alkali metal at different rates. They also may have different thermal tolerances such that an ACPF layer with higher thermal tolerance may be placed against one with lower tolerance so as to protect the one with lower tolerance through the process. The different layers thus may be made from the same polymer or different polymers, may have the same or different forms of alkali metal containing material (e.g., one may have a form that releases alkali metal more slowly and/or at a lower temperature and one may have a form that releases alkali metal more quickly and/or at a higher temperature), may be of the same or different thicknesses, and may have the same or different thermal tolerances. These parameters all permit the overall design and fabrication of the PV device to be more closely controlled to yield the desired results for the particular PV device and fabrication process.

The alkali metal-containing material typically is added to the polymer solution before the polymer is applied as a layer or formed as a film. For example, the alkali metal material can be added to the polymer solution in the same manner as pigments are added to a protective coating system. Alternatively, however, the alkali metal-containing material in any form may be added after the polymer has been applied or cast but before it is cured. For example, the polymer solution may be provided as an uncured film and then an alkali metal containing glass ribbon may be laid into the wet film prior to curing.

As yet another alternative, the alkali metal-containing material could be deposited onto the substrate and the polymer applied over top of the filler. For example, the alkali metal containing material could be provided in the form of a lightweight fiberglass consisting of a very thin woven glass fiber fabric or a non-woven veil. The glass fiber fabric is placed over the substrate and then the polymer film is applied over top of the veil, e.g., by drawdown bar or spray application, and then cured. In such embodiments, the glass fabric (or non-woven veil) can impart (in addition to the alkali metal) improved physical properties of the ACPF, including improved tensile strength. Where the woven glass fabric is thin (e.g., from a fraction of an ounce per yard, up to a few ounces per yard), the resulting ACPF will generally provide a flexible solar PV module. Moreover, this thin glass fabric veil can stabilize the applied ACPF such that surface imperfections which may otherwise be encountered during curing, e.g., “crawling” and “cratering,” are kept to a minimum, or at least substantially eliminated as the ACPF is undergoing the cure process. An example of such non-woven glass veil is a ¾ ounce per square yard soda lime glass fabric veil. Another example is a 1.5 ounce per square yard (60 by 47 weave) woven soda lime glass fabric.

Some embodiments of the ACPF advantageously will be able to (i) withstand high processing temperatures, including those in the range of 500° C. (the deposition temperature of the absorber), for at least five minutes without substantial degradation or off gassing of deleterious species and (ii) provide alkali ions to the CIS or CIGS absorber. It certainly is possible that the ACPF could tolerate only lower temperatures, e.g., at least 300° C., at least 350° C., at least 400° C., or at least 450° C. for at least five minutes without substantial degradation or off gassing of deleterious species, and still be useful if the processing of the PV device does not require such high temperatures, or if a more thermally tolerant coating (e.g., another ACPF or a TSP) is provided over the ACPF.

Of course, for any particular application, the selection of one or more suitable (i) alkali metal-containing materials and forms, (ii) polymers, (iii) loading amounts, and (iv) layer thickness(es) can be determined by routine experimentation so as to achieve sufficient and timely release of alkali metal to the absorber during the absorber deposition process.

Additives to the ACPF and/or TSP

The ACPF and/or TSP also can include additives that provide improved properties to the polymer or resulting film, such as toughness, tensile strength, flexibility, longevity, water resistance, etc. For example, additives that are useful for enhancing the properties of the ACPF and/or TSP are those that can impart a rheological enhancement to the ACPF and/or TSP solution, i.e., impart more uniformity to the cured film in terms of one or more of thickness, surface finish (e.g., fewer defects and craters), more uniform suspension/density of inorganic filler within the polymer film. One example of such additives is fumed silica, and there are many such materials readily available from commercial suppliers. For example, a silane treated fumed silica provided by Evonik Corporation under the trade name Aerosil R 972 is a thixotropic additive that can provide acceptable results, including in applications such as those described herein in which thermal stability is an advantageous property.

Where the ACPF or TSP is intended to be peeled away from the surface on which it is formed (e.g., a flexible substrate), compounds that improve the release characteristics also may be introduced into the ACPF or TSP, the substrate, or to the interface where the ACPF or TSP contacts the substrate.

Applying/Curing the Polymer Film

The polymer can be applied onto a substrate or formed into a stand-alone film in any manner appropriate for the particular application and desired thickness. For example, the polymer can be applied to a substrate by conventional air spray gun (e.g., gravity type), roller, curtain coater, drawdown bar (e.g., 5 mil wet film drawdown bar), or by any other method and/or apparatus that will yield the desired thickness. Alternatively, the composite may be cast into a stand-alone film for later use in making the PV device.

Once applied, the coating composite is typically subjected to one or more heating cycles that drive off the volatile solvent and provide a cured film.

Cure of the ACPF or TSP typically can involve elevating the temperature of the applied polymer composite to drive off the solvent(s) followed by increasing the temperature to the range of at least about 200° C. (390 degrees F.) and holding the temperature at that level for sufficient time for the imidization process to take place. Such curing can be accomplished using conditions and apparatuses that are well known to the industry. Examples include convection and infrared oven systems and flash lamp systems, to name just a few. An alternative cure system that is also applicable to the roll-to-roll processing methods is the use of heated surfaces in contact with the opposite side of the substrate supporting the curing polymer composite. An example is a heated drum that is of appropriate diameter and which rotates at the appropriate speed such that the required contact time is maintained. Of course, a combination of such curing processes may be employed.

For example, the above-described Torlon 4000 T can be applied to a substrate using application techniques which are designed to deliver the appropriate thickness of the solubilized polymer composite medium via mechanical means or alternatively by means of a conventional or airless spray gun, and then cured by subjecting the coated substrate to a controllable temperature regime that progressively increased the temperature from 75° F. to 570° F. over a time interval of approximately 40 minutes.

Where it is desired to have the ACPF and/or TSP remain adhered to a substrate (e.g., a flexible substrate such as a metallic foil), the polymer composite and curing process can be designed so that the resulting ACPF and/or TSP will be tightly adhered to the substrate.

Further, as discussed above, multiple layers of the ACPFs and/or TSPs may be used, and the use of such multiple layers could facilitate the curing process. For example, providing thinner ACPF and/or TSP layers that cure more quickly and easily, and/or with fewer defects, may provide an advantage to providing a single thicker layer.

The ACPF and/or TSP, when cured, typically will have a thickness of at least 0.1 mil. (A mil is 0.001 inch.) The maximum thickness will be dictated by the particular structure desired, but often may be about 2 mil where the resulting PV device is desired to be flexible. In some embodiments where a flexible product is desired, typical film thickness will be from 0.5 mil to 1.5 mil, with 1 mil often providing acceptable results. In the case where the ACPF or TSP is employed as the primary substrate for the PV device, the film thickness may be increased as appropriate to obtain a film with acceptable structural and/or thermal tolerance properties.

Modifying the ACPF Surface

Once cured, the surface of the ACPF optionally may be treated to remove a portion of the upper surface of the film. Depending on the loading of alkali metal containing material in the ACPF and the removal process(es) used, the removal of a portion of the upper surface can yield a relatively smooth surface that comprises alkali metal containing material that is held in place by the surrounding polymer. Thus, the process may comprise scraping, sanding, grinding, polishing, burninshing, abrasion, smoothing or other type of finishing that yields a relatively smooth upper surface. Some type of heat or other finishing treatment also could be used to further smooth, congeal and/or fuse the remaining layer. Depending upon the processes used, the finished ACPF layer may be smoother and may even approach a glass-like consistency. Such surface-modified ACPFs may facilitate application of the electrode and/or absorber layers, and may contribute to a higher overall efficiency of the PV device. Where a relatively smooth alkali metal containing material such as a glass ribbon is inlaid into a polymer to make an ACPF, the polymer layer above the glass ribbon could be removed and the surface finished to provide a relatively smooth, glass-like surface held in place (adhered) by the polymer.

Modifying the surface also may permit the location of the alkali metal-containing material to be controlled relative to its proximity to the absorber layer in order to more accurately manage the migration of the alkali metal into the absorber.

As mentioned previously, the application of a polymer sealant layer also may be used to provide surface modification, i.e., to yield a smooth surface for subsequent deposition of layers such as an electrode and an absorber.

Thermally Stable Polymers (TSP)

As mentioned above, there may be instances where a thermally stable polymer (TSP) is desired, but it is not necessary or desirable to provide alkali metal to the absorber from the polymer layer. In such instances, it may be desirable to provide a polymer film that does not comprise an alkali metal but will tolerate high temperatures, i.e., a TSP. (TSP as used herein means a thermally stable polymer other than an ACPF.). Such TSPs may tolerate, e.g., 500° C. for at least five minutes without substantial degradation or off gassing of deleterious species. If the processing of the PV device does not require such high temperatures, then it would be possible to employ a TSP layer that only needs to tolerate lower temperatures, e.g., at least 300° C., at least 350° C., at least 400° C., or at least 450° C. for at least five minutes without substantial degradation or off gassing of deleterious species. In general, such TSPs need only to be able to withstand the processing temperatures to which they are exposed during fabrication of the PV device without substantial degradation or off gassing of deleterious species.

Examples of TSPs are those formed by a composite of a polymer (described above) that contains an inorganic filler media. Such inorganic filler media may be, for example, in the form of flakes, powders, particles, fibers, ribbons, woven fiber fabrics or veils, microspheres, and combinations thereof. Such an inorganic filled polymer composite is thus not intended to provide a source of alkali metal but instead is intended to enhance and/or help maintain the structural features of the resulting PV device. Alternatively, where it is feasible for the TSP to provide some other compound to the PV device, such other compound may be incorporated into the TSP, provided that the required thermal stability and/or structural integrity is maintained so as to facilitate making and using the PV device. For example, such a coating composition may be formulated such that it can withstand exposure to a higher temperature regime while at the same time imparting an improved dimensional stability to the PV device. By incorporating a loading of inorganic fillers into certain polymer compositions, e.g., a polyamide-imide polymer composition, it is possible to obtain a cured TSP that exhibits good thermal tolerance as discussed above. Such TSPs may be used instead of or in addition to the ACPF discussed above. Such TSPs also may possess a desirable coefficient of thermal expansion (CTE).

Complications may be encountered when applying CIGS absorber films to substrates such as stainless steel and polyimide polymer substrates and appropriate measures may be taken in order to mitigate such complications. One way to deal with the CTE of such substrates is to utilize a martensitic type of stainless steel. Such a stainless steel substrate addresses the thermal expansion because these will influence the properties of semiconductor layers. The use of stainless steel alloy 430 may provide an advantageous substrate from the CTE perspective, since its coefficient of thermal expansion is close to that of the CIGS layer. Specifically when considering the range of 400 degrees C., the CTE of CIGS is approximately 11 ppm per degree C., whereas the CTE of the 430 series stainless falls in this same range, i.e., reportedly at 10-12 ppm per degree C. This suggests that these two materials may provide an advantageous choice in such a bi-layer application. By comparison the “neat” polyimide polymer is approximately 24 ppm per degree C. and the 304 stainless is approximately 20 ppm per degree C. In this example, the inorganic filled solar film medium that is disclosed herein enables this CTE to be brought closer to the CTE of the substrate. Another consideration in the design of this novel composite is the fact that the polymeric composition that is available for selection for this service can be one of that is highly flexible in the temperature range from ambient to 500 degrees C. The design provides for such a polymeric medium to be sandwiched between these two metallic layers whose CTE properties are similar. The result is a means to minimize the possibility of strain related stresses that could result in cracking of the semiconductor layer.

The CTE may facilitate an acceptable deposition of electrode and/or absorber layers by providing good thermal protection and/or physical properties, whether the TSP is used as the substrate for the PV device, or is coated onto a substrate such as a metal foil or other polymer layer. TSPs typically will be used in a thickness within the same ranges of thicknesses as an ACPF.

Typically, CTEs that are closer to that of one or more of the functional layers of the PV device (i.e. the absorber layer or the electrode layers) will provide acceptable results, although in some embodiments, it may be advantageous to have CTEs that are closer to that of the substrate, e.g., to prevent curling of the substrate due to heating or other processing stresses. As mentioned above, such a TSP optionally can be applied to both above the substrate (i.e., on the absorber side) as well as below the substrate.

Even where an ACPF is utilized above a substrate, an optional polymer layer below the substrate typically will not need to provide alkali metal ions to the absorber and thus this optional polymer need not be an ACPF but rather may be a TSP that can withstand the processing temperature (e.g., withstand the processing temperatures for the duration of the fabrication of the PV device without substantial degradation or off gassing of deleterious species), and, advantageously, assist in maintaining the structural properties of the substrate through the manufacturing process.

As mentioned, it may be desirable to match as closely as possible the thermal expansion and contraction properties of this upper and/or lower polymer layer to the substrate so as to prevent curling or other deformation of the substrate in the finished PV device. Indeed, it generally may be desirable to match as closely as possible the thermal expansion and contraction properties of all of the elements of the PV device, including the absorber layer and molybdenum electrode, where it is desirable to prevent defects due to stresses and strains that result from different expansion and contraction of the layered elements of the PV device. Additional advantages that may be provided by such embodiments include acceptable toughness, tensile strength, flexibility, longevity, etc. By providing thermal stability this upper and/or lower ACPF and/or TSP can thus serve a beneficial role in fabrication of the flexible PV device. This beneficial role typically can be even greater if the expansion and contraction properties of the polymer layer(s) is/are reasonably close to those of the substrate.

Finally, as mentioned above for the ACPF, the surface of the TSP optionally may be modified to present a smoother surface.

The filler media that are used herein also may lessen or substantially eliminate the diffusion of impurities from the stainless steel or other substrate used. Such impurities may have a deleterious effect on the properties of the resulting PV absorber. The embodiments described herein also can be used in place of, or in addition to a process by which sodium or other alkali metal is supplied externally during the absorber deposition process, and also permits deposition at a higher CIGS deposition temperature, which is desirable for achieving improved energy conversion.

Efficiencies

Embodiments of PV devices according to the disclosure herein can achieve conversion efficiencies of at least 7%, 8%, 9%, 10%, 11%, 12%, 13%, 14%, 15%, 16% and 17%. Hence, embodiments of this disclosure may provide efficiencies of from 7% to 8%, from 8% to 9%, from 9% to 10%, from 10% to 11%, from 11% to 12%, from 12% to 13%, from 13% to 14%, from 14% to 15%, from 15% to 16%, from 16% to 17% or higher, including from 17% to 18%, from 18% to 19%, from 19% to 20%, and above 20%. Where a CIS or CIGS absorber is employed, higher efficiencies generally will be attained by embodiments in which an alkali metal is provided to the absorber, either through an ACPF or other means.

Embodiments of Flexible PV Devices

The ACPFs and TSPs described herein may be used as part of a flexible PV device. Such devices typically will comprise a flexible substrate film and a solar absorber layer, e.g., a chalcopyrite type of compound (CIS or CIGS type) as a p-type light absorbing layer. Embodiments of such flexible PV devices typically also may contain two conductive layers (electrodes), one on each side of the solar absorber.

While the discussion below is in reference to embodiments in which the PV device is flexible, it should be understood that the use of the ACPF and/or TSP need not be restricted to flexible PV devices but also could be used in semi-flexible and rigid PV devices.

Electrodes

The electrode above the absorber (i.e., on the side exposed to the sun) should allow sunlight to reach the absorber. Such upper electrodes are well known to those skilled in the art, and examples of such electrodes are preferably made of a transparent metal oxide having good conductivity, such as tin oxide doped with from 0.1 to 5% by weigh of fluorine, tin oxide doped with from 0.1 to 30% by weight of antimony, or indium oxide doped with from 0.5 to 30% of tin. Such layers may be of any thickness appropriate to the particular PV device, e.g., 500 nanometers.

The flexible PV device may comprise one or more layers above the upper electrode that serve to improve the properties of the device, including the performance, efficiency, toughness, tensile strength, flexibility, longevity, etc. For example, the flexible PV device may comprise one or more anti-reflection layers above the upper electrode.

As mentioned above, the flexible PV device also may comprise an electrically conductive layer on the underside of the absorber, and such electrodes are well known to those skilled in the art. Such electrical conductive layers typically comprise molybdenum, but also may comprise other suitable metals such as tungsten, nickel, titanium or chromium. The thickness of the back contact layer will be chosen according to the specific PV device and also the metal employed. Acceptable thicknesses of electrodes such as those that comprise molybdenum may be on the order of 1000 nanometers. In addition to providing electrode capability, where an ACPF is used, the underside electrical contact layer must be chosen and fabricated so as to not interfere with the transport of alkali items from the ACPF (discussed below) to the absorber. It is known that under thermal conditions in the range of 500° C., sodium ions will transport through a layer of molybdenum

In alternative embodiments, a metal foil substrate (discussed below) may be used as one of the electrodes. In such embodiments, a connection is provided between the absorber and the metal foil.

Embodiments Comprising an ACPF

Embodiments of the flexible PV device may comprise at least one ACPF (as described above) below the absorber. Because it is a dielectric, the ACPF typically will be positioned below a lower electrode such as a molybdenum electrode described above to as to permit a complete circuit between the absorber and two electrodes.

In embodiments where the ACPF is subjected to high temperatures on the order of 500° C., the ACPF will be designed to withstand such temperatures for at least five minutes without substantial degradation or excessive off-gassing.

As mentioned above, some embodiments of flexible PV devices may comprise two or more ACPFs below the absorber. Alternatively, when appropriate one of the polymer layers may be of the ACPF type whereas a second may be of the TSP type. As also mentioned above, the device typically will have a lower electrode such as molybdenum below the absorber. The first ACPF will be positioned below the lower electrode, although it is possible that one or more layers can be provided between the ACPF and the lower electrode. As mentioned above, considerations in such a design could include but are not limited to: the ease of application, the use of multiple thin films versus a single film application, the benefits relative to the use of multiple layers in order to avoid the consequences of film defects in a single layer, and the provision of different inorganic filler compositions at proximate versus distal layers vis-à-vis the CIS or CIGS absorber. The first ACPF typically will be above a flexible substrate (if one is employed) although, again, there may be one or more layers between the first ACPF and such a flexible substrate.

Where a flexible substrate is employed, another (same or different) ACPF, which can be the same or different as the first ACPF, then may be provided in between the first ACPF and the substrate and/or below the flexible substrate although, again, there may be one or more layers between the second ACPF and the flexible substrate. If placed below the substrate to impart thermal stability to the PV device, the second ACPF might not provide alkali metal ions to the absorber. Alternatively, in some embodiments it is possible that alkali metal from the second ACPF could evolve from the more distal ACPF whereas its rate of diffusion to the absorber is controlled by the more proximate ACPF. In such a design, the alkali metal-containing material typically could be presented in a configuration where it could assist in providing the desired alkali metal dopant delivery. Alternatively, this second ACPF could be replaced by a TSP where alkali metal from this layer is not needed and/or desired.

Embodiments Comprising a TSP

As mentioned above, embodiments of this disclosure may comprise one or more TSP layers. Such TSP can be employed instead of an ACPF in embodiments where providing an alkali metal from the polymer layer to the absorber is not necessary and/or desired. As mentioned above, the TSP generally may be used instead of an ACPF as the primary or base substrate, or above a substrate such as a polymer or metal foil (e.g., stainless steel foil) and in such an application, the TSP can serve as a dielectric medium, as well as a material that can slow, reduce or eliminate the diffusion of impurities from the substrate, which impurities would otherwise have a deleterious effect on the semiconductor layer. If the ACPF itself is the primary or base substrate, then the TSP could be coated onto the ACPF. Advantageously, for the reasons discussed above, the CTE of the TSP will facilitate fabrication of the PV device.

The Substrate

As mentioned above, the ACPF or TSP may be used as the primary or base substrate for the PV device. Alternatively, a different substrate may be used as the primary or base substrate for the PV device, and the ACPF or TSP may be provided above the substrate. In such cases, the substrate may be flexible, semi-flexible or rigid, and its role, at least in part, will be to provide a foundation upon which the ACPF and/or TSP can be formed.

Where the PV device does comprise such a flexible substrate, it may be intended to remain through the use of the PV device or may be intended to be separated from the rest of the device at some point. The flexible substrate may be made of any material that suits the intended use and fabrication of the PV device. Where the flexible substrate must withstand high temperatures, it advantageously is able to withstand high temperatures without deleterious affects.

The substrate may be, for example, a thin, flexible metal or foil such as stainless steel foil. Alternatively, it may be a high temperature resistant polymer sheet material, which optionally may have a composition similar to the polymer that is used in the ACPF or TSP. Examples of commercial products include KAPTON by DuPont, and UPILEX-S by Ube Corporation of Japan. The thickness of the flexible substrate will be determined by the specifications and intended use of the PV device. The substrate typically should be of a thickness and composition to facilitate maintaining the integrity of the device through processing, handling and ultimately application of the device. Embodiments typically will employ substrates of thickness between 1 mil and 10 mils, with thicknesses between 1 mil and 4.0 mils typically providing acceptable results. A thickness of about 2 mil provides acceptable results. Where a polyimide film such as KAPTON is employed, a thickness in the range of 1-4 mils may provide acceptable results.

Where a flexible polymer material is used as the substrate, advantageously it will provide acceptable thermal resistance, e.g., it will be able to withstand temperatures in the range of 450° C. and higher for the time interval of exposure involved in the CIGS deposition and annealing process; however when such flexible substrate is coated with the ACPF or TSP, the substrate which would tolerate only lower temperatures is thereby altered such that the resulting laminate is able to withstand even higher CIGS deposition temperatures due to the ACPF or TSP, e.g., up to 500° C. and higher for time intervals in the range of minutes. Furthermore, the coated substrate likely will encounter a reduced amount of thermal stress caused by the differential strain rates between the absorber and conductor layers on one hand and the substrate on the other.

Optionally, the PV device can comprise a semi-flexible or rigid base substrate, onto which one or more of the ACPF and/or TSP, electrode(s) and absorber are provided. In some embodiments, the substrate may be retained in use of the PV device, in which case the PV device would be either semi-flexible or rigid. In other embodiments, the substrate may be present only for the formation of one or more layers. For example, a substrate may be employed merely to facilitate formation of the ACPF or TSP, and then separated therefrom before further addition of layers onto the ACPF or TSP.

Thus, a temporary flexible, semi-flexible, or rigid base substrate can be used as a support during the formation of the ACPF, TSP and/or PV device production process and when appropriate the temporary base can be separated. Where the finished PV device layer is intended to be separated from this supporting substrate, the substrate may be chosen to facilitate release and/or the base and/or ACPF or TSP may include additives that can enhance the ability of the substrate and the resulting PV device to be separated, and/or or one or more additional intermediate layers can be provided that can enhance release. In embodiments where the substrate is intended to remain through the absorber deposition process, the substrate can be optionally chosen and/or configured in such a manner that it enhances the thermal and dimensional stability of the ACPF or TSP during the absorber deposition process. Alternatively, where the substrate is to be separated following formation of the ACPF and/or TSP, then its thermal properties likely will be less important, and it only will need to be able to withstand the temperatures necessary for curing the ACPF or TSP.

Thus, for example, a stand alone ACPF or TSP can be fabricated by forming the film onto a smooth surface, and then separating it from that surface upon cure. That ACPF or TSP then can be used as the substrate for fabricating additional layers of the PV device. In such instances, it may be advantageous to use the surface of the ACPF or TSP that is exposed upon separation from the release substrate as the surface upon which subsequent layers, e.g., the electrode and absorber, are formed. For example, an ACPF can be applied to a borosilicate glass substrate which is polished and/or treated with a release aid. It has been found, e.g., that when an ACPF comprising a woven glass fabric is formed on a smooth release substrate and then removed, the surface of the ACPF which was against the smooth substrate may be substantially as smooth and uniform as the surface onto which it was cast. In such embodiments, no modification of the surface, e.g., sanding or application of a sealant may be necessary or desirable.

As mentioned above, thin metal films also may be used as substrate materials for flexible PV devices according to this disclosure. Examples include molybdenum, stainless steel, and titanium foils. Such substrate materials should be thermally resistant such that they can withstand the temperatures involved in the processing of the specific PV device in which they are a part. For example, the deposition of the absorber layer can include thermal exposure to temperatures in the range of 500° C. and thus in some embodiments the metal film may be exposed to such temperatures. If coated on one or both sides with an ACPF and/or TSP, then it may not need to be as thermally tolerant. The metal film advantageously should withstand such temperatures encountered in the manufacturing process without any significant amount of undesired heat aging-related loss in the flexibility or other physical properties of the film. Additionally, if the underside of the foil is to remain uncoated through the absorber deposition process, then the metal should be able to resist the highly corrosive atmosphere that can be involved in the deposition of a CIGS absorber layer. One example of such a metal foil is AISI 430 alloy. Such metal foil can be obtained commercially at various film thicknesses. Examples of thicknesses that may provide acceptable results include 0.036 inches (20 gage) and 0.060 inches (16 gage). As with the polymer substrates discussed above, flexible metallic substrates also may be coated on the topside (absorber side) and/or underside with an ACPF and/or TSP.

The ACPF or TSP typically also will provide a dielectric separation between metal foil and the electrically conductive electrode layer that is below the absorber. However, some embodiments provide for the metal foil (discussed above) to serve as one of the electrodes, e.g., instead of a molybdenum electrode. In such devices, there must be provided an electrical connection between the absorber and the foil in order to permit the foil to serve as the electrode. This could be accomplished by any number of methods.

Additional Layers

As mentioned above, the flexible PV device may optionally comprise one or more layers positioned throughout the device that may provide one or more advantageous properties to the device, including enhancing the device's solar operation (for those layers typically positioned above the absorber, e.g., anti-reflection layers), toughness, tensile strength, flexibility, longevity, peelability, etc. Such optional layers can include sealers, e.g., for an ACPF, TSP and/or other layers in the PV device. In some embodiments, such a sealant layer can be used to affect the rate of sodium migration, e.g., from an ACPF to a CIGS deposition region. Optionally, a contact adhesive and an optional release sheet could be applied to the underside of the PV device to facilitate the application of a PV device to a surface. In this way, the PV device could be provided in sheet or roll form for ready application to a surface.

Flexibility

As discussed above, embodiments of the ACPFs disclosed herein are flexible. Such embodiments have the ability to endure a reasonable amount of deflection and the corresponding planar strain before they crack or otherwise become functionally degraded. Advantageously, the ACPF will have sufficient flexibility to be rolled onto a mandrel that has a diameter selected from the group consisting of 10 inches, 8 inches, 6 inches or 4 inches, without beginning to crack, becoming functionally degraded or otherwise lose the ability to function as an ACPF as described above, e.g., to withstand heat and provide alkali metal to the absorber on deposition.

Embodiments of Methods of Making Flexible PV Devices

The PV devices can be fabricated in any number of ways. Embodiments in which a flexible substrate is provided can be prepared by roll-to-roll or batch processing.

In some embodiments, a flexible substrate comprising a polymer that has good thermal resistance, e.g., up to 450° C., e.g., KAPTON, can be provided with a layer of thermally resistant polymer below the substrate as well as one above the substrate. The layer above the substrate may be an ACPF or TSP for the reasons discussed above. The polymer layer below the substrate can be an ACPF, a TSP or any other polymer that can withstand the temperatures that will be encountered in the particular process. In some embodiments, the application of the absorber will require the lower polymer layer to withstand temperatures of 500° C. or more for at least five minutes.

Advantageously, in such embodiments, the polymer layers above and below the substrate will help maintain the structural properties of the substrate. For example, in embodiments where the substrate is not thermally resistant up to 500° C., coating the substrate on both sides with polymer layers that can withstand temperatures of 500° C. or more for at least five minutes so that the deposition of the absorber layer will not significantly affect the substrate. For example, polymer substrates that typically cannot withstand temperatures of 500° C. may curl or otherwise structurally deform upon heating to such temperatures. By providing high thermal resistant layers above and below, however, the polymer substrate can remain without substantial deformation or at least undergo substantially less deformation than otherwise would occur in the absence of the thermally resistant layers.

In such embodiments, it is advantageous to employ polymer layers above and below the substrate that will expand and contract with heating and cooling at approximately similar rates to the substrate such that the substrate will remain relatively flat or undergo substantially only minimal curling or deformation following processing. Advantageously, during the process of making the PV device, the amount of expansion of the ACPF and/or TSPs will not exceed the amount of expansion of the substrate by more than 50%, 40%, 30%, 25%, 20%, 15%, 10%, 7.5%, 5%, 2.5% or 1%. Likewise, during the process of making the PV device, the amount of contraction of the ACPFs and/or TSPs advantageously will not exceed the amount of contraction of the substrate by more than 50%, 40%, 30%, 25%, 20%, 15%, 10%, 7.5%, 5%, 2.5% or 1%.

In yet other embodiments, the ACPF or TSP will be formed on a release substrate (typically smooth) and then separated from the release substrate and used as a stand alone substrate in further process steps.

Skilled artisans will readily recognize many different processes based on the disclosures of the various combinations of layers and treatments described above.

As discussed above with the ACPFs, embodiments of the PV devices disclosed herein are flexible. Such embodiments have the ability to endure a reasonable amount of deflection and the corresponding planar strain before they crack, become functionally degraded, or lose any significant amount of operational integrity. Thus, embodiments of the PV devices disclosed herein can be rolled onto a mandrel that has a diameter selected from the group consisting of 10 inches, 8 inches, 6 inches or 4 inches without the PV device cracking, becoming functionally degraded, or losing a significant amount of operational integrity (i.e., the conversion efficiency of the PV device will remain at a value of greater than 90%, greater than 95%, greater than 98% or greater than 99% of the efficiency of the PV device prior to being rolled on the mandrel).

Optional Heat Treatment

One or more of the polymer layers optionally can be heat treated following curing. Such heat treatment may provide improved operational consistency and functional reliability due to the thermal behavioral properties of the polymer film. “Heat aging” of the composite coating is carried out at a temperature that is higher than the temperature that is necessary to achieve a fully cured film. During this elevated temperature treatment, a thermoplastic behavior occurs and there is an associated plastic flow of the polymer medium, which simultaneously also will affect any filler medium that is present in the polymer layer. For example, in an ACPF, such a heat treatment may provide improved uniformity and operational consistency of the alkali metal resource layer.

Embodiments of PV Devices in Combination with Batteries

As noted above, a PV device of this disclosure optionally may be combined with a battery to store the electrical energy produced by the PV device. It will be understood, however, that the batteries discussed herein need not be combined with the PV devices of this disclosure, but instead may be combined with PV devices other than the types disclosed herein, including other types of CIGS PV devices. In this configuration the output voltage of the PV device matches or substantially matches the charging voltage of the battery. For example, the output voltage of the PV device could be within 1%, 2.5%, 5%, 7.5%, 10%, 15%, 20% or 25% of the charging voltage of the battery.

Acceptable batteries for use in the embodiments described herein include lightweight, thin film, flexible batteries. Such batteries include thin film solid electrolyte battery systems that are based on the presence of lithium ions, as thin film batteries using lithium alloys as the anode can exhibit an advantageously high power-to-weight ratio. Embodiments of such batteries include lithium graphene batteries. Within the embodiments of such lithium graphene batteries are those in which the recharge voltage is in the range of from 1.0 to 1.5 volts, 1.5 to 2.0 volts, 2.0 to 2.5 volts, 2.5 to 3.0 volts, 3.0 to 3.5 volts, 3.5 to 4.0 volts, 4.0 to 4.5 volts, 3.0 to 4 volts, 3.0 to 4.5 volts, 4.5 to 5.0 volts and greater than 5.0 volts.

Advantageously, embodiments of combination PV/battery devices can provide an operationally simplified electrical energy collection and storage system wherein the electrical energy provided by a solar photovoltaic module and the energy storage system are in close proximity. Embodiments described herein further can provide a lightweight, thin-film, flexible solar cell with a lightweight thin-film, flexible solid electrolyte battery, and in some embodiments, these two elements share a common supporting substrate, e.g., a layer of 430 stainless steel at 4 mil film thickness.

Embodiments of the PV devices and combination PV/battery devices described herein can be protected from degradation resulting from exposure to moisture and oxygen. Coatings such as those described in U.S. Pat. No. 6,413,645 B1 “Ultrabarrier Substrates” and U.S. Pat. No. 6,623,861 B2 “Multilayer Plastic Substrates,” the disclosures of which are expressly incorporated herein by reference in terms of the coatings described therein, can provide acceptable results. The coatings can be applied to cover part or all of the PV device or combination PV/battery device.

In some embodiments, the coatings are applied so as to encapsulate, i.e., cover all of the PV device or combination PV/battery device so as to provide protection, while still permitting electrical current to exit the solar cell. Advantageously, the coating in such embodiments is able to both (1) transmit the sunlight to the PV device, e.g., the coating can be transparent or substantially transparent, and (2) transmit current generated in the PV device, i.e., the coating is electrically conductive. The electrical conductivity thus provides a pathway to bring the electrical power generated by the PV device outside of the boundary of the encapsulation coating without adversely affecting the operational performance of the PV device. In some embodiments, therefore, a transparent or substantially conducting layer is deposited onto the p-type front layer and this serves as the front contact which serves to conduct the current that is generated by the PV device and thus the encapsulation coating does not interfere with the function of the PV device. Persons of skill in the art will appreciate that such transparent conducting oxides can provide transparent electronic circuits that provide diode functionality.

As noted above, embodiments of the combination PV/battery devices can share a common electrode, e.g., stainless steel, which can serve as the supporting substrate for both the PV device and the battery. In such embodiments, this opto-electronic layer is simply extended such that it engages the corresponding contact that is provided by the common electrode. A similar approach is used in dealing with the thin film, flexible, solid electrolyte battery. Such encapsulation can be used in embodiments discussed below such that this conductive material extends beyond the area covered by the encapsulation medium, this exposed conductor provides the contact to achieve the electrical connection between the PV and the battery, as discussed below.

One example of an encapsulation coating that can be used in embodiments described herein is comprised of multiple thin transparent or substantially transparent layers that alternate between a polyacrylate polymer that serves as a smoothing layer and an inorganic metal oxide barrier layer. Such a coating can provide acceptable results in terms of providing both protection and electrical conductivity. In such embodiments, the electrical energy output from the solar PV device can be delivered from the PV device by conductive pathway that is electrically continuous over all or a portion of the entire surface of both the PV device surface and the battery surface. Where the device includes a battery, the output from the PV portion of the device can be delivered to the battery, as discussed below. Embodiments which employ such encapsulation can permit operation at the relatively low voltage range that is sufficient for charging a battery.

In embodiments of such coatings, the metal oxide layer can be chosen so as to be conductive when illuminated with light and non-conductive otherwise. For example, one or more layers comprising a transparent or substantially transparent electronics layer which is conductive when illuminated with light and non conductive otherwise may be used. This opto-electronic technology in the conductive layer can be designed to lessen or prevent an undesirable backflow or discharging of energy from the battery when there is a “no sunlight” condition. The use of transparent n-type conducive media such as ZnO, SnO₂, In₂O₃:Sn can be combined with the p-type transparent conductor such as CuAlO2. This technology provides the mechanism for achieving pn type heterogeneous diodes and pn homogeneous diodes.

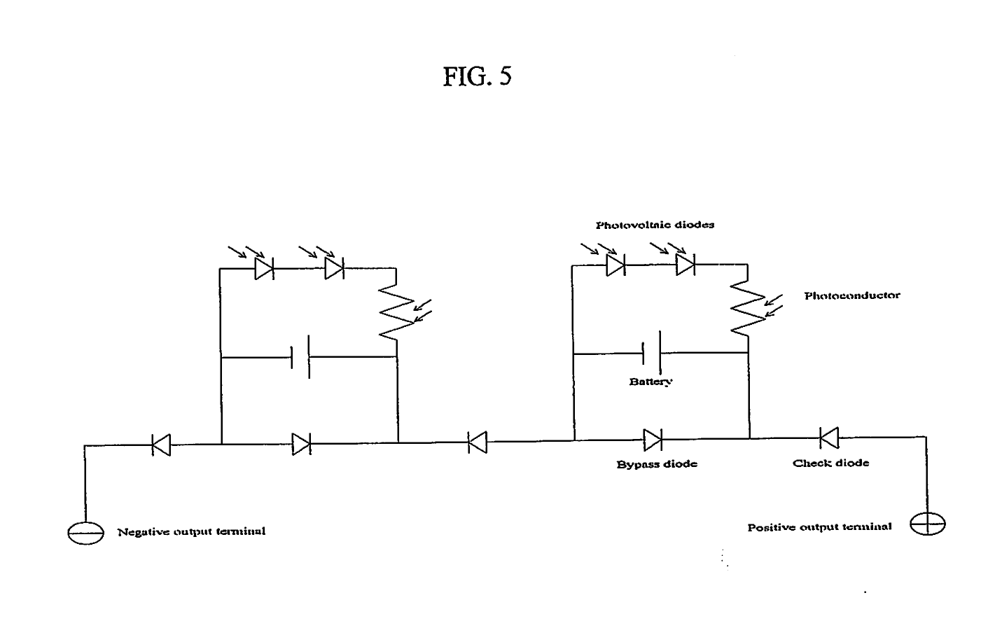

Further embodiments of this disclosure thus provide systems that prevent or lessen any drain of power from a charged storage battery when there is no light. In such systems, the connecting circuitry allows delivery of electrical power but reduces or eliminates current backflow. FIG. 5 is a schematic diagram that illustrates one embodiment of an electrical circuit that may be used with the combination PV/battery devices described herein. FIG. 5 illustrates only one example of a way in which two or more combination PV/battery devices could be connected together. This schematic provides for an electrical connection circuit between the PV absorber and the battery (to allow flow of energy from the PV absorber to the battery) to be positioned outside the PV/battery device. This schematic diagram illustrates but one embodiment of a configuration of a parallel series circuit network for a distributed PV/battery device array. The components in the illustration are the PV devices, photoconductors, rechargeable thin film battery, bypass diode, check diodes (i.e., a diode that conducts electricity under specific conditions), all connected through a circuit, e.g., a thin film printed plastic membrane circuit on a connector as described below.

Embodiments such as that illustrated in FIG. 5, illustrate one example of a way to configure the batteries and photovoltaics such that the photovoltaic voltage cannot over-charge the battery. The interconnecting or “shunt” circuitry can include multiple features that can improve the performance of the PV/battery device and/or an array that is formed from connecting multiple PV/battery devices. For example, the shunt circuit can include bypass diodes in such a configuration that provides a way to address the instability that would otherwise might present a problem if an isolated areas of the solar array encounters shadowing or darkness, or there is a localized failure of the PV device or the battery. The shunt circuit may include a check diodes within the current output electrical route to prevent back flow of current through the array. The above are intended here only as examples of the types of basic building block circuits that might be used in configuring the electrical design for interfacing the PV and battery components. Further, they may be repeated as appropriate when multiple PV/battery devices are connected in an array. Other embodiments of basic building block circuits that can be employed to achieve one or more of the stated goals will be recognized by those skilled in the art.

As noted above, the design of the system's electronic circuits may incorporate what is sometimes referred to as “smart circuitry”. While not wishing to be bound by any particular theory, the following brief overview on the use of diodes as applied to the solar PV/battery devices may be helpful

The following properties of a p-n junction may be useful. A p-doped semiconductor is relatively conductive. The same is true of an n-doped semiconductor, but the junction between them is a nonconductor. This nonconducting layer, occurs because the carries of the electrical charge in the case of n-type and p-type silicon attract and eliminate each other in a process called recombination. By manipulating this non-conductive layer, p-n junctions are commonly used as diodes which are circuit elements that allow an electrical flow in one direction but not in the other (opposite) direction. This property is explained in terms of forward bias and reverse bias, where the term bias refers to an application of electric voltage to the p-n junction.

Use of Forward Bias Diode Systems

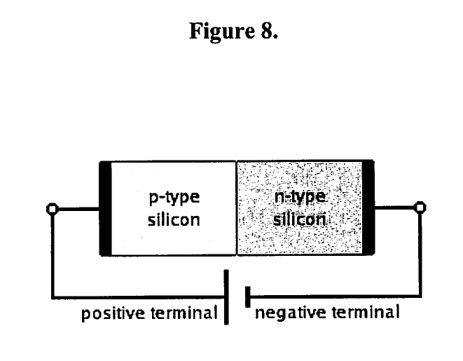

The diode interconnect may be designed in such a manner that the P-type semiconductor material is connected to the positive terminal of the battery and the N-type semiconductor material is connected to the negative terminal, as shown in FIG. 8. In such a configuration the p-n junction conducts.

A silicon p-n junction in forward bias.

In this solar cell/battery connect configuration, the holes in the P-type region and the electrons in the N-type region are pushed towards the junction. In such case the positive charge applied to the P-type material repels the holes, while the negative charge applied to the N-type material repels the electrons. As electrons and holes are pushed towards the junction, the distance between them decreases. This provides the means for achieving the desired level of electropotential barrier. With increasing forward-bias voltage, the depletion zone eventually becomes thin enough that the zone's electric field can't counteract charge carrier motion across the p-n junction, consequently reducing electrical resistance and accordingly the amount of current that can flow through the diode.

A silicon p-n junction in reverse bias.

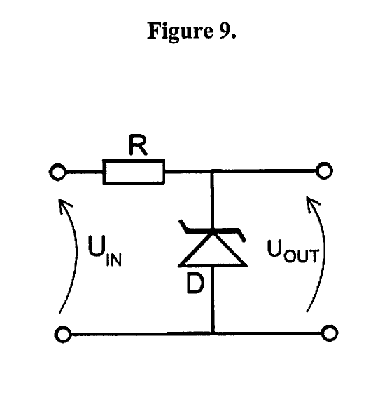

The illustration at FIG. 9 addresses a role of the diode in the photovoltaic solar cell service. In this case the diode is reverse biased, the voltage at the cathode is higher than that at the anode. Therefore, no current will flow until the diode breaks down. Connecting the P-type region to the negative terminal of the battery and the N-type region to its positive terminal, corresponds to reverse bias.

A p-n junction diode allows electric charges to flow in one direction, but not in the opposite direction; negative charges (electrons) can easily flow through the junction from n to p but not from p to n and the reverse is true for holes. When the p-n junction is forward biased, electric charge flows freely due to reduced resistance of the p-n junction. When the p-n junction is reverse biased the resistance becomes greater and charge flow is minimal.

As discussed above, the PV absorber and battery of the combination PV/battery device may be connected by means of circuitry that is provided within an appropriately configured shunt device, which shunt circuitry permits a managed flow of the energy provided by the solar PV device to the battery. In some embodiments, current flux may be managed by an electrical circuit design that provides control of the direction of current flow, as well as management of the voltage within the system. In some embodiments this management system can respond to localized shadowing of a part of the solar array, as well as any localized malfunctioning of the array.

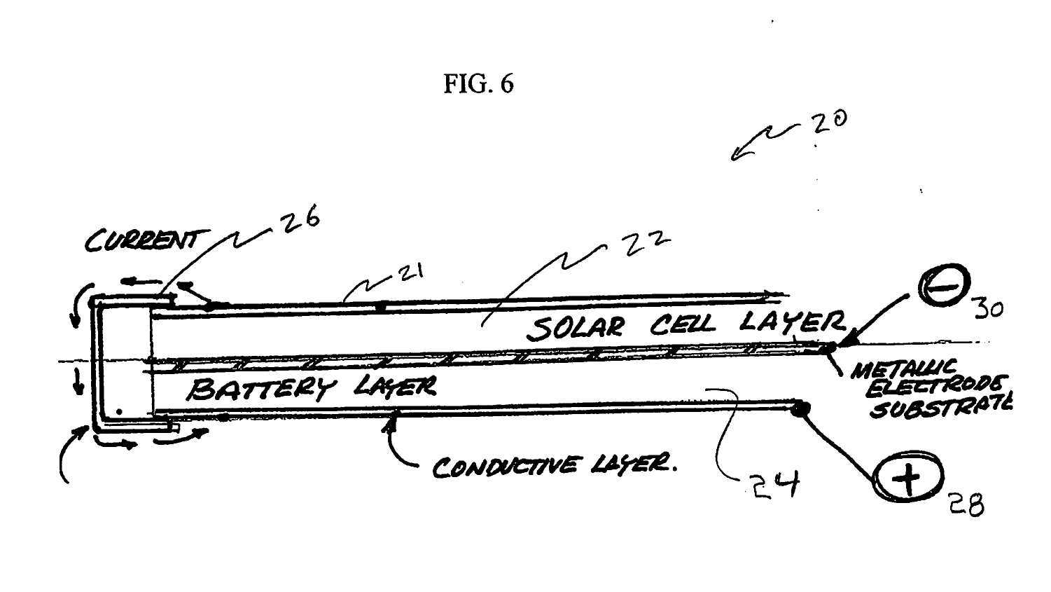

As described above, in some embodiments a PV device and battery share a common conductive electrode. In such embodiments, the PV device and battery may be interconnected in a number of different ways. One such way is by a connector apparatus as shown in FIG. 6. Embodiments of shunt circuit connectors described herein can provide the support for physically connecting PV/battery elements and also the electrical and electronic circuitry as well as the current carrying conductor features. This shunt circuit is typically will be made a part of the system at some point after the PV/battery device is fabricated, and often may be added in the field Advantageously, embodiments of such shunt circuits will incorporate therein a sufficient level of conductivity to transfer the current loads with minimal resistance losses.

For example, configurations that may be employed include the arrangement of battery elements in series. The size of the individual battery elements are constrained such that there is an optimization of the output current levels from the battery to achieve an optimum balance of power output that can be realized from a given electronic circuit design. Further, assuming that the PV device will deliver an energy conversion efficiency in the range of 15 percent, then for a one sun solar incidence, such a PV device will deliver 150 watts per square meter of surface area. In such case, the current flux that would be imposed in such a circuit will be easily manageable.

Referring to FIG. 6, an embodiment of a combination PV device and battery 20 is shown. This device provides electrical power transfer between the surface layer 21 of the PV device 22 and the battery layer 24 via shunt circuit 26, as well as electrical power transfer to the point where the current is extracted through the positive and negative contacts 28 and 30, respectively. Using a shunt circuit such as that depicted by 26, which can be coupled to the combination PV device/battery, e.g., in the field, can reduce or eliminate stresses that otherwise might be encountered with rigid connections and/or as a result of thermal stresses on the combination PV device/battery. As noted above, the conductive surface layer can be transparent or substantially transparent, and can include layers (e.g., zinc oxide doped layers) that permit photo conductive current flow that accommodates the charging operation and reduces or eliminates undesirable discharge under non-charging conditions.

Embodiments of Array Connectors for PV Devices

As mentioned above, multiple PV devices and/or combination PV/battery devices, can be physically and electrically connected in series, thereby enabling the production of electrical output at different voltages. Upon reading this disclosure, skilled artisans will recognize ways in which such devices can be so connected.

Embodiments of array connectors provided herein can physically and electrically connect such devices so as to form arrays. In such embodiments, the electrical interconnect circuitry and other electronics (e.g., conditioning electronics) can be external to the array connector, or may be incorporated into the array connector itself, or may be housed in a separate piece that can be attached to the array connector and made part of the array.

Embodiments of array connectors according to this disclosure may be of any predetermined length. Advantageously, however, they may be modular such that one array connector may be permanently or releasably coupled to another, either directly or through other types of connectors, so as to create arrays of virtually any size. Such designs will enable series-connected arrays of PV devices and/or combination PV/battery devices to be created as desired. Further, by providing suitable electronics, advantageously as part of the array connectors themselves, current and voltage characteristics of the resulting arrayed units can be controlled. For example, the current and voltage can be controlled such that that absence of sunlight or even localized shadowing of a portion of the array does not result in undesired effects such as parasitic electrical back-feed behavior within the system. As but another example, the system can be programmed to electrically isolate a damaged and/or malfunctioning PV device such that the overall system operation is not compromised. Such electronics can be controlled by a computer, e.g., through a direct connection with a computer near or within the array and/or via a web-based approach in which data about the status and condition of each of the individual panels as well as the entire array are transmitted to a computer at a remote location that monitors and/or manages the array. Such embodiments, therefore, permit a “smart” hybrid power generation and collection array can be made, which can permit an efficient and operationally simplified approach to PV usage and management. The array connectors also may contain rectifying contact layers, or rectifying may be performed external to the array connector.

The array connectors may be comprised of any material that will support the PV devices in the array, e.g., an extruded, dielectric polymer to provide the structural features of the array connector. The use of a dielectric material further can provide electrical isolation if any electrical connections or circuits are provided within the array connector. If electrical connections or circuits in the array connector are desired, then the connectors may further comprise one or more types of metallic media such as wire, wire cloth, expanded metal, corrugated or fingered strips to provide electrical connection as desired.

Embodiments of the array connectors can provide for a relatively uniform current flux across the surface of the respective cell and ultimately its extraction at the cell edge. Such array connectors may further, optionally utilize the standard interdigitized grid geometry that is used to further enhance the conductivity performance of the conductive coating that covers the surface of the cell. Such grid technology is known to persons skilled in the field of solar cell technology.

Embodiments of the array connectors disclosed herein can further optionally incorporate printed electrodes. The use of copper nano-ink, which is delivered by piezoelectric inkjet printing methodology, is but one example of production techniques that can optionally be used in this design. The internal surface of the array connector device thus can also serve as a repository for the electrical interconnect system which includes features such as rectifying diodes, schottky diodes and associated functional features and connectors which can be deposited using automated printing techniques such as that described above.

Embodiments of the array connectors described herein also may incorporate a current carrying busbar type of connector feature for efficiently carrying current within the network. Such array connector embodiments also provide an enclosure into which an electrical circuit resides and which circuit provides management of the current flux, the voltage and protection in the event of isolated operational upsets within the system. Elements that may be utilized in such circuits include passive components such as resistors and diodes.

As noted above, the circuitry also can provide for connection of the solar PV layer to the storage battery layer in such a manner that the electrical energy does not discharge or substantially does not discharge through the solar cell when there is insufficient voltage associated with the incident light. Optionally, the output of the battery elements can be connected in a series configuration such that the output power of the array can be matched to the voltage demands upon the system.

As mentioned above, the shunt circuit is designed to electrically connect the combination PV/battery devices in a manner that can be readily accomplished, e.g., during field installation of an array system. In embodiments, the shunt circuit also may be designed so as to assist in positioning the PV/battery device into the supporting array connector, or other structural element, as well as to functionally interface the PV/battery device with the array connector or other electrical system, e.g., of a building.

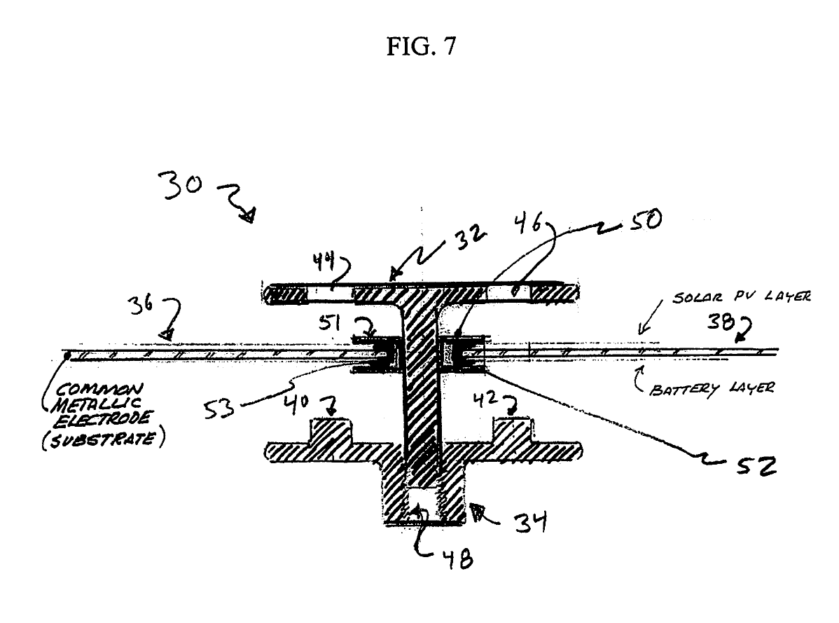

One embodiment of an array connector which may be used to link combination PV/battery devices into an array is provided in FIG. 7.

In FIG. 7, the illustrated two-piece array connector provides for mechanically interlocking embodiments of combination PV/battery devices such as those shown in FIG. 6. The array connector 30, comprising top and bottom interconnecting pieces 32 and 34, assures positive alignment of the PV/battery devices 36 and 38 by the upset pins 40 and 42 which are located on bottom piece 34. When the top and bottom pieces are compressed together, the upset pins 40 and 42 of the bottom piece fit into corresponding perforations 44 and 46, respectively.

Following insertion of the top piece 32 into the bottom piece 34, the top piece 32 is held firmly by an interlocking mechanism that is illustrated by teeth 48 in the bottom piece, which would hold the top piece firmly in place. Any interlocking mechanism that will be apparent to skilled artisans upon reading this disclosure may be used. In some embodiments, the interlocking mechanism also provides for releasable coupling so that PV/battery devices and/or connectors may be readily replaced in the array.

In operation, as the top piece 32 is compressed into the bottom piece 34, the “C” shaped shunt circuits 50 and 51 such as those described above is compressed so that their edges are forced into engagement with the appropriate regions along the edge of the PV layers and the battery layers so as to create a circuit by which current may flow from the PV absorbers to the batteries. Insulating inserts such as that shown by 52 and 53 may be provided to prevent undesired contact between PV device and the shunt circuit. For example, when a substrate is used as a common electrode, as described above, the insulating inserts 52 and 53 may prevent undesired contact with the shunt circuits 50 and 51. Alternatively, the current connector could be designed so as to prevent contact with the common electrode or to provide insulation in any part of the current connector that might touch the electrode. The array connector 30 thus also illustrates the availability of unused surfaces or internal areas of the connector where electrical control circuitry could be located. As noted above, however, the electrical control circuitry could be located apart from the connector, including in a different type of connector that is employed in the array so formed. This “C” shaped shunt circuits 50 and 51 illustrated in FIG. 7 are intended only as a graphical illustrations of the shunt circuits that are described above, which circuits may as described above include various electronic circuitry features to enhance the performance of the PV/battery devices and/or array.

### EXAMPLES

The following examples are intended to exemplify embodiments within the scope of this disclosure. They are not intended in any way to limit the scope of this disclosure or the claims appended hereto.

### Example 1

This example demonstrates the technique of producing a flexible solar cell wherein a glass surface is bonded to a flexible polymer substrate using an ACPF that can tolerate high temperatures. The process consists of drawing a molten rectangular glass ribbon through a suitable forming apparatus, followed by cooling the ribbon and subsequently depositing the said rectangular glass ribbon onto a sheet of polymer film that has been previously mounted onto a rotatable cylindrical mandrel.

A flexible solar substrate films were prepared that consisted of a two mil thick film of polyimide polymer sheeting Upilex S as the substrate onto which a rectangular glass ribbon array was deposited so as to yield a uniform soda lime glass surface. In this case the glass ribbon's cross-sectional dimensions were 300 microns wide by 30 microns thick. There was a spacing of approximately 100 microns between the ribbons. (Note: It is anticipated that ribbon width can be adjusted to as much as 600 to 800 microns width at a thickness of 50 microns and with a ribbon to ribbon spacing of as little as 50 microns.) In this case the binder polymer (adhesive medium that secures the glass ribbons to the polyimide substrate film) was the polyamide imide (PAI) polymer, Torlon 4000 T. This polymer had been solubilized in a 1-methyl-2-pyrrolidinone solvent. After contacting the glass ribbon and the substrate polyimide sheeting, the bonding process was accelerated by means of heating to 300° F. to volatilize this solvent followed by a second stage of heating at approximately 390° F., to achieve the conversion to polyimide. The result was a robust yet flexible composite that presented a soda lime glass surface comprised of a Schott B-270 glass medium of 110,000 psi tensile strength and a Refractive Index (RI) of 1.52.

### Example 2

This example provides embodiments that may be incorporated in a roll-to-roll production process. In these embodiments, an inorganic medium is mixed into the polymeric binder and this mixture is applied, e.g., to a supporting polymer substrate or alternatively to a metal foil substrate. This composite coating can be applied to one side or to both sides of the substrate.

In these embodiments, the polyamide-imide polymer used is Torlon 4000 T. and it is solubilized in a 1-methyl-2-pyrrolidinone solvent. The polymer then may be applied using a 5 mil wet film drawdown bar or by conventional air spray gun (Gravity Type). Curing is achieved by subjecting the coated substrate to a controllable temperature regime that progressively increased the temperature from 75° F. to 390° F. over a time interval of approximately 40 minutes.

The alkali silicate particles used are an anhydrous alkali silicate, SS-C-200 (PQ Corp.). Particle Size is such that 97% will pass through a 200 mesh screen. The weight percent of Na₂O is 37.7 percent and the SiO₂ is 65.4 percent.

The glass flakes used in this example, Microglas RCF-160, are produced by Nippon Sheet Glass. This is 9-13 percent Na₂O and the nominal particle size is 160 micron with 65 percent of the weight content having a thickness range of 40-160 microns.

Glass microspheres used in this example were provided by 3M Corporation under the tradename of Zeospheres. This is a soda lime glass sphere designated as 3M S-60/10,000.

A silane treated fumed silica is also used in this example (from Evonic Corporation under the trade name Aerosil R 972). This is a thixotrope that can impart desired rheological properties to these mixtures.

ACPF 1—This exemplifies an embodiment of a composite formulation comprising a 2.25 to 1-weight loading of soda lime glass microspheres to the weight of polymer:

| 1-methyl-2-pyrrolidinone | 64.3 percent |
|---|---|
| Polyamide-imide resin | 10.7 |
| Soda lime glass microspheres | 4.1 |
| Silane treated fumed silica | 0.9 |

This composition was applied to the polyimide sheet and cured to yield a tough and robust film system. In a separate application, this coating composition was applied to the substrate using a drawdown bar as well as by means of a spray gun. Application thickness could be controlled within the range of 6 mils wet-down to the range of one mil wet. Curing of the resulting applied composition was accomplished by placing the thus coated polyimide sheet on a thermal pad that delivered the temperature regime needed to cure the composite.

ACPF 2—This exemplifies the formulation of a composite that comprises a glass flake filler medium incorporated into the high temperature polymer solution.

| 1-methyl-2-pyrrolidinone | 66.4 percent |
|---|---|
| Polyamide-imide resin | 11.1 |
| Soda lime glass flakes | 22.2 |
| Silane treated fumed silica | 0.3 |

This composition was applied to a polyimide-imide sheet and cured to yield a tough, tightly adhered and robust film system which was observed to impart a substantial reduction in the coefficient of thermal expansion (CTE), as compared to the uncoated polymeric film. Also, when this composition was applied to both sides of the polymeric (polyamide-imide) sheet, the CTE was seen to be further improved for the intended use.

ACPF 3—This formulation illustrated an ACPF comprising both an alkali silicate and soda lime glass flakes in the polymer composite:

| Polyimide-imide solution consisting of 14.3 percent | 47.6 percent |
|---|---|
| polymer loading in 1-methyl-2-pyrrolidinone | |
| Alkali silicate | 6.9 |
| Soda lime glass flakes | 1.3 |
| Silane treated fumed silica | 1.3 |
| 1-methyl-2-pyrrolidinone | 42.9 |

The above formulation was applied to both a polyimide substrate and a metal foil substrate. In both cases the result was a tough and tightly adhered and robust film that could provide a substantial inventory of sodium during a CIGS deposition process.

ACPF 4—This formulation illustrated a composition that is highly filled with alkali silicate).

| Polyamide-imide solution at 14.3 percent | 84.6 percent |
|---|---|
| Alkali Silicate | 12.9 |
| Silane treated Fumed Silica | 2.6 |

This composition is applied to both a polyamide-imide substrate and a metal foil substrate, using the 5 mil drawdown bar. The result was a highly filled polymer composite which exhibited improved CTE properties and provided a substantial inventory of sodium within its composition.

ACPF 5—This formulation illustrated a composition that is highly filled with soda lime glass powder.

| | | |
|---|---|---|
| 1 methyl-2 pyrrilodone | 7.2 | percent |
| Toluene | 8.8 | |
| Polyamide-imide polymer | 4.1 | |
| Silane treated fumed silica | .1 | |
| Soda lime glass powder (7 micron mean particle size) | 18.8 | |

This composition is applied to a release medium using a 20 mil drawdown bar and cured using an impingement oven. The result is a highly filled polymer composite that is useful in making a CIGS type solar device. A CIGS absorber layer deposited on such a composite will achieve significant levels of alkali metal dopant.

### Example 3

This example illustrates one embodiment of an optional layer that may be applied to provide a sealant for one or more layers of the PV device where desired, including, e.g., an ACPF layer or a layer made from an inorganic filled polymer composite coating. The optional layer comprises a neat polymeric film, which may be applied in any thickness, but which advantageously in some circumstances may be applied as a very thin coating to seal an ACPF. In such circumstances, such a coating also could be used to affect the rate of sodium migration from the ACPF to a CIGS deposition region.

| 1-methyl-2-pyrrolidinone | 85.7 percent |
|---|---|
| Polyamide-imide resin | 14.3 |

This coating could be easily applied, e.g., over a previously applied ACPF or inorganic filled composite coating. Where used, the resulting film will present a smoother surface for subsequently applied layers such as a molybdenum electrode and/or CIGS absorber layer.

### Example 4

Secondary Ion Mass Spectrometry (“SIMS”) analyses of CIGS absorbers deposited onto three ACPF substrates made in accordance with this disclosure illustrate the ability of such ACPF substrates to provide sodium to the CIGS absorber layer. The SIMS analyses confirm the ability of ACPFs to provide sodium to the CISG absorber in different amounts depending on the composition of the ACPF. By using ACPFs of different compositions, therefore, only routine experimentation will be required to obtain CIGS layers in which sodium or other alkali metal(s) is/are provided to the CIGS absorber in a desired amount. Thus, by routine experimentation with the various parameters discussed in this disclosure, e.g., polymer composition, alkali metal forms (s) and loading amount(s), heating regime, and the optional use of a sealant layer, CIGS layers can be obtained in which sodium or other alkali metals is present in the CIGS absorber in desired amounts and at the desired depths of the absorber. Moreover, as seen below, the ACPF can provide a substantially uniform distribution of sodium or other alkali metal in the CIGS layer for a significant depth of the CIGS layer. By using ACPFs of different compositions, therefore, only routine experimentation with the various parameters discussed above, e.g., polymer composition, alkali metal source(s) and loading amount, heating regime, and use of sealant(s), will be required to obtain CIGS layers in which sodium or other alkali metals is provided to the CIGS absorber in a substantially uniform amount to a desired depth or across substantially all of the thickness of the absorber. Further, not only can substantially uniform amounts be provided through most, substantially all or all of the CIGS absorber layer, but by routine experimentation with the above parameters, even gradients of desired amounts at desired depths can be created. Moreover, as with sodium and other alkali metals, the ACPFs described herein also may be used to provide other dopants to the CIGS layer in the same way as the sodium or other alkali metal is provided, and as with the alkali metals such as sodium, such dopants can be provided either substantially uniformly across the depth of the absorber or according to a desired gradient.

In each of the three samples discussed below, an ACPF layer was prepared as described. A molybdenum layer then was provided on top of the ACPF layer, and then a 1.2 μm thick CIGS absorber layer was deposited onto the molybdenum layer. A fourth sample, which served as the control, was prepared using crystalline glass instead of an ACPF layer. The SIMS analyses of the CIGS absorbers then was performed by the Evans Analytical Group, which is a known provider of SIMS analyses. (SIMS is a technique used in materials science and surface science to analyze the composition of solid surfaces and thin films by sputtering the surface of the specimen with a focused primary ion beam and collecting and analyzing ejected secondary ions. These secondary ions are measured with a mass spectrometer to determine the elemental, isotopic, or molecular composition of the surface. SIMS is a very sensitive surface analysis technique, and is able to detect elements present in the parts per billion range.)

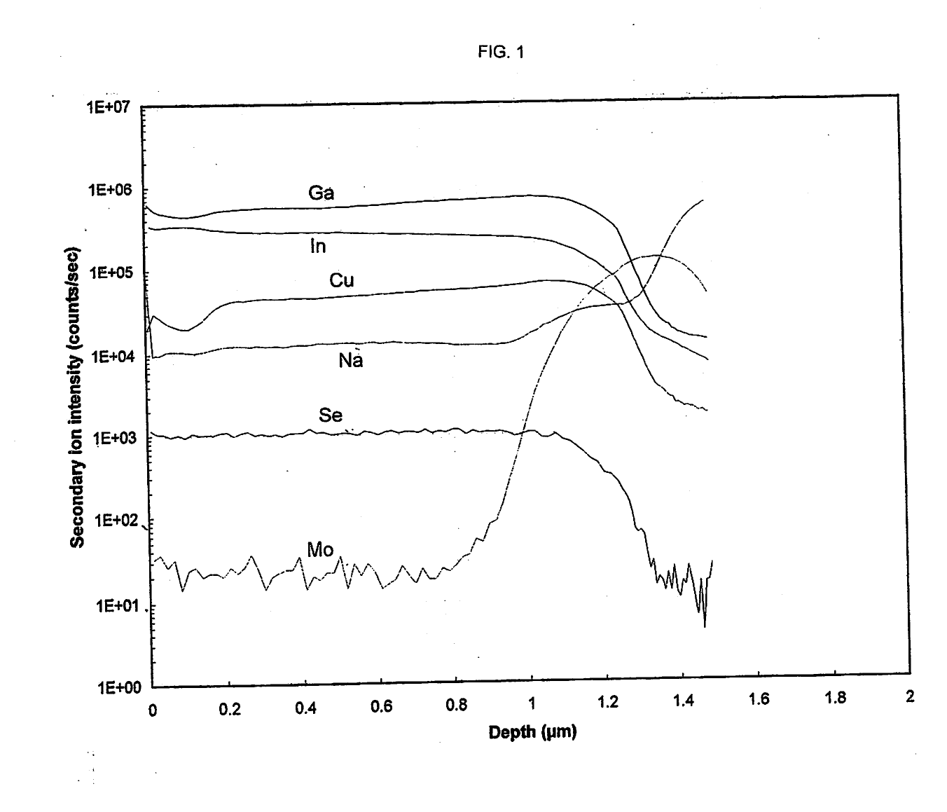

SAMPLE 1—FIG. 1 is a SIMS analysis of an absorber layer that was deposited on a substrate comprising an ACPF layer. The ACPF composition was comprised of a polyamide-imide polymer solution medium into which was dispersed a combination of approximately 1:1 mixture of 7 micron mean particle size soda lime glass powder filler medium and an anhydrous alkali silicate filler powder, at a loading level of approximately 30 percent by weight of inorganic filler in the dry film. This mixture was applied as approximately 20 mil wet film to a 1.5 ounce per square yard woven glass fabric. The CIGS absorber layer was subsequently deposited using a thermal regime of approximately 425 degrees C.

As seen in FIG. 1, the amount of sodium in the CIGS absorber layer stayed substantially uniform throughout much of the thickness of the CIGS layer. The secondary ion intensity in the CIGS layer indicates that the sodium level yielded approximately 1×10⁴ counts per second from approximately the proximal free surface of the CIGS, as is illustrated in these data. This sodium concentration is relatively constant from the near surface depth of from about 0.025 μm to a depth of about 0.9 μm. There is an increased level of sodium content in the CIGS at the further advancing depth. This analysis shows that the there is an increase in the sodium level to about 3×10⁴ counts per second at the interfacial boundary of the CIGS layer with the molybdenum layer, which occurs at approximately 1.2 μm depth. Thus, by using a combination of sodium forms as described in this example, a remarkably uniform deposit of sodium may be obtained through more than 70% of the thickness of the absorber, i.e., until a depth of at least about 0.9 μm.

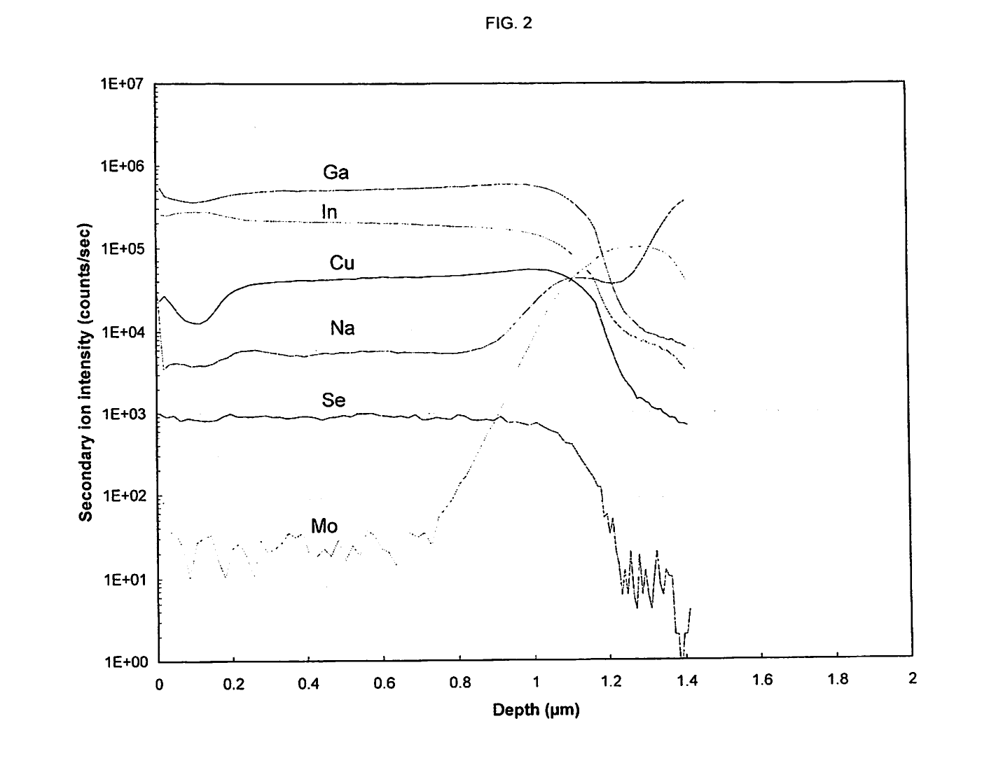

SAMPLE 2—FIG. 2 is a SIMS analysis of an absorber layer that was deposited on a substrate comprising an ACPF layer. The ACPF composition was comprised of a polyamide-imide polymer solution medium into which was dispersed a 1:1 mixture of 7 micron mean particle size soda lime glass powder filler and an anhydrous alkali silicate powder medium at a loading level of approximately 30 percent inorganic filler by weight in the dry film. This mixture was applied to a type 304 stainless steel foil substrate and cured. The CIGS absorber layer was subsequently deposited using a thermal regime of approximately 425 degrees C. The secondary ion intensity in the CIGS layer for sodium was in the range of approximately 2.5×10⁴ to 6×10⁴ counts per second.

As seen in FIG. 2, the amount of sodium in the CIGS absorber layer was again substantially uniform throughout a substantial portion of the CIGS absorber. The secondary ion intensity in the CIGS layer for sodium in the CIGS absorber was approximately 3.5×10³ counts per second at a depth of from about 0.025 μm. There was a quantifiable variation in the amount of sodium up to about 6×10³ counts per second at a depth of between 0.2 and 0.3 μm, as the depth of the analysis continued, the amount of sodium stayed fairly constant to yield from about 5×10³ counts per second to about 6×10³ counts per second until about 0.8 μm depth and then rose to about 6×10⁴ counts per second at the boundary of the CIGS layer at 1.2 μm. Thus, it can be seen that by using a combination of sodium contributing ingredients in the ACPF, as described in this example, a substantially uniform deposit in which the counts per second of sodium differed by less than a factor of two through more than about 60% of the thickness of the absorber, i.e., until a depth of about 0.8 μm.

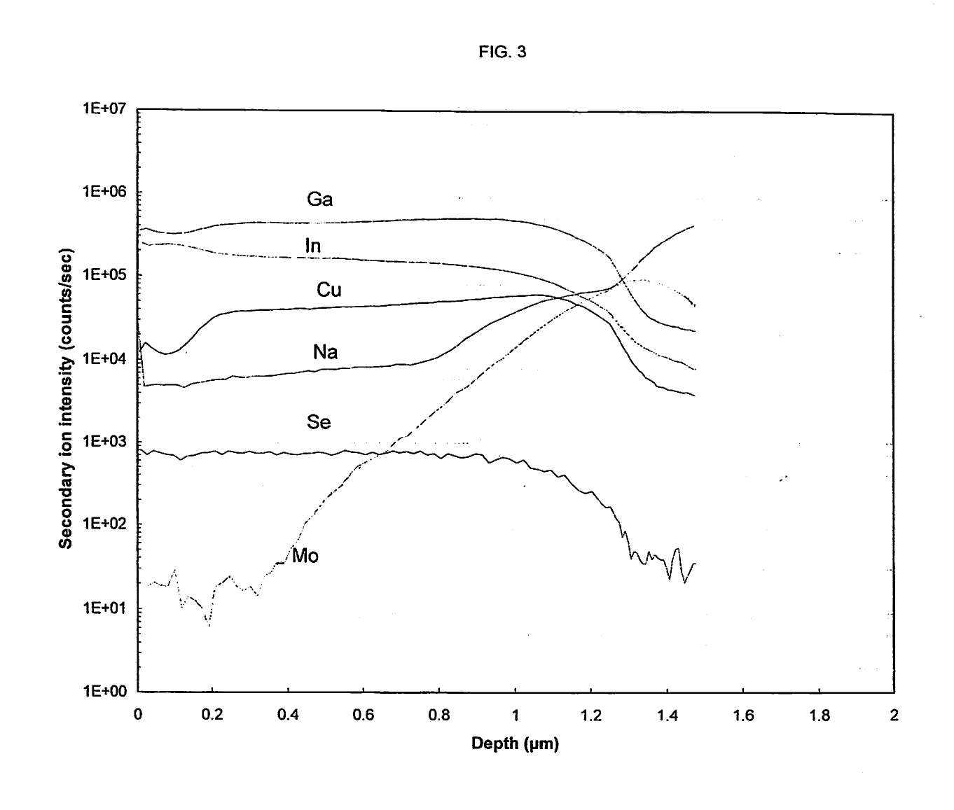

SAMPLE 3—FIG. 3 is a SIMS analysis of an absorber layer that was deposited on a substrate comprising an ACPF layer. The ACPF composition was comprised of a polyamide-imide polymer solution medium into which was dispersed a 7 micron mean particle size soda lime glass powder filler at a loading level of approximately 60 weight percent in the cured film. This composition was applied to a polyimide substrate and cured. The CIGS absorber layer was subsequently deposited onto this substrate using a thermal regime of approximately 425 degrees C.

As seen in FIG. 3, the amount of sodium in the CIGS absorber layer exhibited a slightly increasing gradient as the depth of the CIGS layer increased up to about 0.8 μm, but overall was still substantially uniform. Thus, the secondary ion intensity in the CIGS layer for sodium in the CIGS absorber was approximately 4.75×10³ counts per second at a depth of from about 0.025 μm. There was a less than a two-fold increase up to about 8×10³ counts per second at a depth of about 7 μm. The amount then rose to about 7×10⁴ counts per second at the boundary of the CIGS layer at 1.2 μm. Thus, by using a combination of sodium forms as described in this example, a substantially uniform deposit in which the counts per second of sodium differed by less than a factor of two through more than about 50% of the thickness of the absorber, i.e., until a depth of about 0.7 μm. Also, as shown herein, while the counts per second showed a substantially uniform deposit, there was a slightly increasing gradient across the depth up to about 0.7 μm and then a more significant increase up to the 1.2 μm boundary, illustrating that a combination of sodium forms can be used to provide gradients as desired.

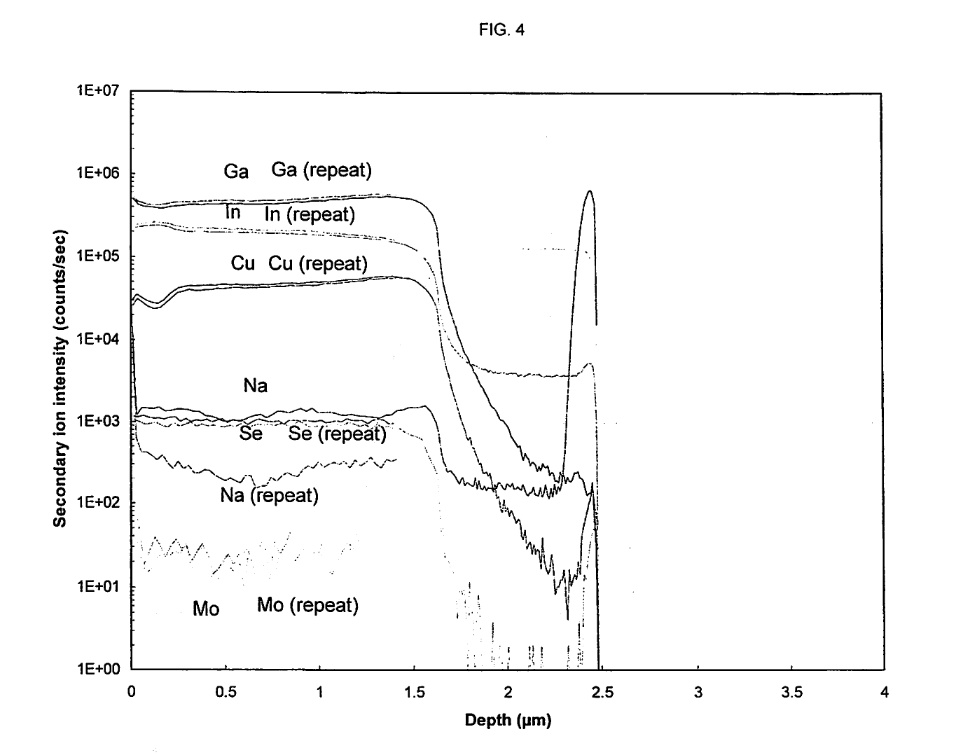

CONTROL—FIG. 4 is a SIMS analysis of a control device in which an absorber layer as described in Samples 1-3 was deposited on a substrate comprising crystalline glass. As seen in FIG. 4, the amount of sodium in the CIGS absorber layer approximately between about 1.25×10³ and 1.75×10³ counts per second throughout the thickness of the absorber.

The foregoing results illustrate that substantial amounts of alkali metal, in this case sodium, can be achieved in the CIGS absorber by employing ACPF layers in accordance with embodiments of this disclosure. Thus, amounts of sodium that yield SIMS counts per second of from 2×10³ up to more than 5×10⁴ are readily obtainable. Accordingly, amounts of alkali metal such as sodium can be provided in the CIGS absorber to yield SIMS counts per second of from 2×10³ to 5×10³, from 5×10³ to 7.5×10³, from 7.5×10³ to 1×10⁴, from 1×10⁴ to 2.5×10⁴, from 2.5×10⁴ to 5×10⁴, from 5×10⁴ to 7.5×10⁴, from 7.5×10⁴ to 1×10⁵, and from 1×10⁵ to 5×10⁵ or higher as desired. Thus included within these ranges are SIMS counts per second of from 2×10³ to 3×10³, from 2×10³ to 3×10³, from 2×10³ to 3×10³, from 3×10³ to 4×10³, from 4×10³ to 5×10³, from 5×10³ to 6×10³, from 6×10³ to 7×10³, from 7×10³ to 8×10³, from 8×10³ to 9×10³, from 9×10³ to 1×10⁴, from 1×10⁴ to 2×10⁴, from 1×10⁴ to 2×10⁴, from 2×10⁴ to 3×10⁴, from 3×10⁴ to 4×10⁴, from 4×10⁴ to 5×10⁴, from 5×10⁴ to 6×10⁴, from 6×10⁴ to 7×10⁴, from 7×10⁴ to 8×10⁴, from 8×10⁴ to 9×10⁴, from 9×10⁴ to 1×10⁵, and above 1×10⁵ as desired, e.g., from 1×10⁵ to 5×10⁵ or higher.

Further, as shown substantially uniform amounts of alkali metal such as sodium can be achieved across greater than 50% of the thickness of the CIGS absorber. Thus, amounts of alkali metal such as sodium that yield SIMS counts per second that do not differ by more than a factor of 1.25, 1.5, 1.75 or 2 across 20%, 30%, 40%, 50%, 60%, 70%, 80%, 90% and 100% of the thickness of the absorber are possible using the ACPFs and methods described herein. It will be appreciated that within such substantially uniform amounts there can be slightly increasing and/or decreasing gradients.

Further, as shown, substantial gradients also can be provided. Thus, amounts of alkali metal such as sodium that yield SIMS counts per second that differ by more than a factor of 2, 2.5, 3, 4, 5, 6, 7, 8, 9 and 10 across 20%, 30%, 40%, 50%, 60%, 70%, 80%, 90% and 100% of the thickness of the absorber are possible using the ACPFs and methods described herein.

### Example 5

This example demonstrates the application of the ACPF to a stainless steel foil substrate, using a roll to roll production technique.

The first step addresses the manufacture of the polymeric composition: This is accomplished as follows: 4050 grams of a 15 percent solution of Torlon 4000 polymer was dissolved in NMP and this solution was added to a high shear vacuum dispersion mixer. To this was added a pigment composition of 650 grams of spherical 6000 glass powder, 650 grams of 5 micron mean particle size silica powder, and 100 grams of Aerosil R-972 fumed silica. This mixture was subjected to high shear dispersion for one hour and then a second resin blend was added consisting of 6400 grams of an 18.8 percent solution of Torlon 4000 in NMP. Next step involved transport of this completed ACPF composition to the roll to roll production facility.

After thinning to application viscosity of approximately 400 cps, the mixture was subjected to a vacuum system that removed entrained air bubbles. Next the mixture was strained through a 150 mesh strainer and then applied to the stainless steel foil substrate, using a slot die coating apparatus that was an integral part of a pilot scale roll to roll production line. This line was configured to include an unwind station, slot die coater, two-zone high impingement dryer and rewind station.

The substrate that was coated consisted of a stainless steel ribbon comprised of ten inch wide by four mil thick 304 alloy stainless steel. The length of this ribbon was in excess of 100 feet. In this example the line speed was set at 10 feet per minute and the as thinned-material flow rate to the slot die coater was 112 grams per minute.

The resulting deposition of the ACPF coating formulation is calculated to be 1.5 mils dry film thickness.

The resulting cured film was observed to be well adhered, uniformly covering the substrate. The “as-coated” stainless steel substrate was observed to possess the same flexibility as is observed with the uncoated stainless steel substrate.

This ACPF coated stainless steel ribbon was subjected to a second stage cure that was achieved by exposing the specimen to a temperature of 260 degrees C. for 20 minutes. This second stage cure event did not result in any noticeable change in the physical appearances of the composite, with the exception of a slight darkening of the color.

Optical surface profile analysis revealed that the resulting surface presented a RMS average value of 0.14 microns and average roughness of 0.11 microns.

### Example 6

This example demonstrates the application of the ACPF to a martensitic type of stainless steel. This design addresses the manufacture of the CIGS solar cell on the stainless steel substrate with emphasis on thermal expansion, surface roughness, and resistance to diffusion of impurities, since these may influence the properties of the following semiconductor layers. The use of stainless steel alloy 430 is used here as the substrate, since its coefficient of thermal expansion is close to that of the CIGS layer. Specifically when considering the range of 400 degrees C., the CTE of CIGS is approximately 11 units whereas the CTE of the 430 series stainless falls in this same range, i.e. reportedly at 10-12 units. This suggests that these two materials may provide a advantageous match. (By comparison the “neat” polyimide polymer is approximately 24 units and the 304 stainless is approximately 20 units.)

In this example, the film substrate material comprises a highly filled polymeric medium and thus its CTE is brought closer to the CTE of the substrate, as a result of its inorganic filler medium. An additional feature of this composite is the fact that the polymeric composition that has been selected is highly flexible in the temperature range from ambient to 500 degrees C. This flexibility feature is effectively utilized in this design because the polymeric medium is sandwiched between two layers of metallics whose CTE properties are similar. The resulting configuration reduces the possibility of strain related stresses that could result in cracking of the semiconductor layer.

In this case the substrate used was a 10 inch wide 430 stainless steel foil at a film thickness of 4 mils. The first step involved the manufacture of the coating composition: wherein 4000 grams of IM-9320 (blend of polyimide polymer, POSS and NMP) is weighed into mixing vessel. To this is added a pigment composition of 1300 grams of Sphericel 6000 glass powder and 200 grams of Aerosil R-972 fumed silica. This mixture was subjected to highs shear dispersion (at atmospheric pressure and temperature) for approximately 5 minutes. (during this time the temperature of the mixture was observed to rise by 70 degrees F.). This is followed by a resin add of 6400 grams of IM-9310.

The next step involved dilution with NMP approximately 1:1 by weight. This is followed by heating to 130 degrees F. to facilitate spray application using a gravity feed HVLP spray gun.

Curing of the applied film is as follows:

Air dry for one hour

Oven cure at rising temperature from 100 degrees C. to 260 degrees C. over one hour.

One hour at 400 degrees C.

After the above scenario, the cured film was exposed to 500 degrees C. (to simulate the conditions that are encountered in CIGS film deposition) with the result that there was no apparent degradation of film integrity as a result of the thermal event.

1. A photovoltaic (PV) device comprising a first alkali metal-containing polymer film (ACPF).

2-6. (canceled)

7. A PV device according to claim 1, further comprising a photovoltaic absorber of light energy.

8. A PV device according to claim 7, wherein the absorber is a CIS or CIGS absorber.

9-10. (canceled)

11. A PV device according to claim 1, further comprising a substrate positioned below said first ACPF.

12. (canceled)

13. A PV device according to claim 11, wherein said substrate comprises a metal foil, polymer, or inorganic composite.

14-29. (canceled)

30. A method for making a PV device comprising the steps of:
providing a first alkali metal-containing polymer film (ACPF); and
depositing a photovoltaic absorber layer thereon which is useful for conversion of solar energy,
wherein during the production of the device the step of depositing the photovoltaic absorber provides a mechanism for the transport of said alkali metal from the ACPF into the absorber layer.

31. (canceled)

32. A method according to claim 30, wherein the alkali metal is in a form comprising soda lime glass filler medium in the form of a rectangular glass ribbon, glass flake, woven glass fabric, glass microspheres and/or a particulate powder.

33-35. (canceled)

36. A method according to claim 30, wherein the absorber is a CIS or CIGS absorber.

37. A method according to claim 30, further comprising the step of providing a printed electrode medium between the absorber and the first ACPF.

38. A method according to claim 37, further comprising the step of providing said printed electrode medium by means of a nano-ink solution.

39. (canceled)

40. A method according to claim 38, wherein said substrate comprises a metal foil, polymer, or inorganic composite.

41-42. (canceled)

43. A method according to claim 38, further comprising the step of providing a polymer layer as an integral part of the substrate.

44. A method according to claim 43, wherein said polymer layer below the substrate comprises a second ACPF, or wherein said polymer layer comprises an inorganic media-filled polymer.

45. (canceled)

46. A method according to claim 43, wherein said polymer layer comprises a polyimide polymer.

47-89. (canceled)

90. A PV device according to claim 1, further comprising a thin film, flexible, battery capable of storing energy created by the PV device.

91. A PV device according to claim 90, wherein the battery includes the presence of lithium ions, or is a lithium graphene battery.

92-95. (canceled)

96. A PV device according to claim 90, wherein the PV device and the thin film battery are electrically connected using a diode functional shunt circuit that manages the electrical communication between the photovoltaic absorber and the battery.

97. A PV device according to claim 96, wherein the diode functional shunt circuit reduces or eliminates flow of current between the photovoltaic absorber in the PV device and the battery in the absence of sunlight, and/or wherein the shunt circuit prevents the battery from over charging, and wherein said circuit consists of printable inorganic semiconductor materials.

98-100. (canceled)
